(19) United States
(12) Patent Application Publication
(10) Pub. No.: US 2025/0275266 A1
(43) Pub. Date: Aug. 28, 2025

(54) SOLID-STATE IMAGING DEVICE

(71) Applicant: SONY SEMICONDUCTOR SOLUTIONS CORPORATION, KANAGAWA (JP)

(72) Inventor: JUN OKUNO, KANAGAWA (JP)

(21) Appl. No.: 18/858,763

(22) PCT Filed: Mar. 16, 2023
(86) PCT No.: PCT/JP2023/010435

§ 371 Date: Oct. 22, 2024

(30) Foreign Application Priority Data
Apr. 28, 2022 (JP) 2022-074995

(51) Int. Cl. H10F 39/18; H04N 25/773; H10F 39/00

(52) U.S. Cl. CPC H10F 39/182; H04N 25/773; H10F 39/8037; H10F 39/809; H10F 39/811

(57) ABSTRACT

Provided is a solid-state imaging device capable of suitably forming a capacitor for a floating diffusion portion. A solid-state imaging device of the present disclosure includes: a first substrate; a photoelectric conversion unit provided in the first substrate; a floating diffusion portion provided in the first substrate; and a capacitor including a first electrode electrically connected or connectable to the floating diffusion portion, a second electrode different from the first electrode, and a ferroelectric film or an antiferroelectric film provided between the first electrode and the second electrode.

### TECHNICAL FIELD

The present disclosure relates to a solid-state imaging device.

### BACKGROUND ART

A technique for improving a dynamic range of a solid-state imaging device by electrically connecting a capacitor to a floating diffusion portion of the solid-state imaging device is known. In this case, disposing a capacitor or a switch transistor for the capacitor in the solid-state imaging device causes problems of poor area efficiency of the solid-state imaging device and complicated manufacturing processes of the solid-state imaging device. Furthermore, when a thin film transistor is used as the switch transistor for the capacitor in order to improve the area efficiency of the solid-state imaging device, there is a problem that the manufacturing cost of the solid-state imaging device increases.

### CITATION LIST

### Patent Document

Patent Document 1: Japanese Patent Application Laid-Open No. 2005-328493
Patent Document 2: Japanese Patent Application Laid-Open No. 2013-033896

### SUMMARY OF THE INVENTION

### Problems to be Solved by the Invention

The present disclosure provides a solid-state imaging device capable of suitably forming a capacitor for a floating diffusion portion.

### Solutions to Problems

A solid-state imaging device according to a first aspect of the present disclosure includes: a first substrate; a photoelectric conversion unit provided in the first substrate; a floating diffusion portion provided in the first substrate; and a capacitor including a first electrode electrically connected or connectable to the floating diffusion portion, a second electrode different from the first electrode, and a ferroelectric film or an antiferroelectric film provided between the first electrode and the second electrode. As a result, for example, the dynamic range can be improved without using a switch transistor, and the capacitor for the floating diffusion portion can be suitably formed.

Furthermore, in the first aspect, the ferroelectric film may contain hafnium (Hf), zirconium (Zr), niobium (Nb), scandium (Sc), yttrium (Y), lanthanum (La), germanium (Ge), or silicon (Si). Thus, for example, a suitable ferroelectric film can be formed.

Furthermore, in the first aspect, the first electrode may be electrically connected to the floating diffusion portion, a source or a drain of a transfer transistor, and a gate of an amplification transistor. As a result, for example, each pixel can be configured without using a switch transistor.

Furthermore, the solid-state imaging device according to the first aspect may further include a wiring that applies a predetermined voltage to the second electrode. As a result, for example, a capacitance of the capacitor can be changed by this voltage.

Furthermore, in the first aspect, a sum of a capacitance of the floating diffusion portion and a capacitance of the capacitor may be switchable to at least two types of values. As a result, for example, the dynamic range can be improved by this switching.

Furthermore, in the first aspect, the sum of the capacitance of the floating diffusion portion and the capacitance of the capacitor may be switchable using hysteresis of the capacitor. Thus, for example, the dynamic range can be improved using the hysteresis.

Furthermore, in the first aspect, the first electrode may be electrically connectable to the floating diffusion portion, a source or a drain of a transfer transistor, and a gate of an amplification transistor via a switch transistor. As a result, for example, each pixel can be configured using a switch transistor.

Furthermore, in the first aspect, a sum of a capacitance of the floating diffusion portion and a capacitance of the capacitor may be switchable to three or more types of values. As a result, for example, the dynamic range can be improved by this switching.

Furthermore, in the first aspect, the sum of the capacitance of the floating diffusion portion and the capacitance of the capacitor may be switchable using hysteresis of the capacitor and on/off of a switch transistor between the capacitor and the floating diffusion portion. As a result, for example, the dynamic range can be improved using the hysteresis and the switch transistor.

Furthermore, in the first aspect, the sum of the capacitance of the floating diffusion portion and the capacitance of the capacitor may be switchable using hysteresis of the capacitor and adjustment of a voltage applied to the capacitor. As a result, for example, the dynamic range can be improved using the hysteresis and the voltage adjustment.

Furthermore, in the first aspect, the solid-state imaging device may further include a lens provided on a second surface side of the first substrate, and the capacitor may be provided on a first surface side of the first substrate. As a result, for example, the above-described capacitor can be applied to a back-illuminated solid-state imaging device.

Furthermore, the solid-state imaging device according to the first aspect may further include, on the first surface side of the first substrate, a first region including a transfer transistor, a second region including a pixel transistor other than the transfer transistor, and a third region including a logic circuit. As a result, for example, the above-described capacitor can be applied to a back-illuminated solid-state imaging device while providing the first to third regions.

Furthermore, the solid-state imaging device of the first aspect may further include: a second substrate bonded to the first substrate; and a logic circuit provided on the second substrate. As a result, for example, the above-described capacitor can be applied to a solid-state imaging device configured using two substrates.

Furthermore, the solid-state imaging device of the first aspect may further include a third substrate bonded to the first substrate and the second substrate, and the capacitor may be provided in the third substrate or in a third insulating film provided in the third substrate. As a result, for example, the above-described capacitor can be applied to a solid-state imaging device configured using three substrates.

Furthermore, in the first aspect, the first electrode may be provided in a first insulating film provided on the first substrate, and the second electrode may be provided in a second insulating film provided on the second substrate. As a result, for example, the above-described capacitor can be disposed on a bonding surface between the first insulating film and the second insulating film.

Furthermore, in the first aspect, the capacitor may be provided in an element isolation groove. As a result, for example, a region in the element isolation groove can be effectively used for the above-described capacitor.

Furthermore, in the first aspect, the capacitor may be shared by a plurality of pixels. As a result, for example, the number of capacitors in the solid-state imaging device can be reduced.

Furthermore, the solid-state imaging device according to the first aspect may further include, as the capacitor, a first capacitor including the second electrode to which a predetermined voltage is applied from a first wiring, and a second capacitor including the second electrode to which a predetermined voltage is applied from a second wiring. As a result, for example, different voltages can be applied to these capacitors for each capacitor.

Furthermore, in the first aspect, the capacitor may be electrically connected or connectable to the floating diffusion portion by a second contact plug different from a first contact plug that electrically connects the floating diffusion portion and an amplification transistor. As a result, for example, it is possible to reduce variations in parasitic capacitance for each pixel.

Furthermore, the solid-state imaging device according to the first aspect may further include, as the capacitor, a plurality of partial capacitors electrically connected or connectable to the floating diffusion portion, and a selection unit that selects one or more partial capacitors from the plurality of capacitors, and sets a sum of capacitances of the selected partial capacitors as a capacitance of the capacitor. As a result, for example, the dynamic range can be improved by selecting the partial capacitors.

### BRIEF DESCRIPTION OF DRAWINGS

FIG. 1 is a block diagram illustrating a configuration of a solid-state imaging device of a first embodiment.

FIG. 2 is a circuit diagram illustrating a configuration of the solid-state imaging device of the first embodiment.

FIG. 3 is a plan view illustrating a structure of the solid-state imaging device of the first embodiment.

FIG. 4 is a cross-sectional view illustrating a structure of the solid-state imaging device of the first embodiment.

FIG. 5 is a cross-sectional view illustrating a structure of a solid-state imaging device according to a first modification of the first embodiment.

FIG. 6 is a cross-sectional view illustrating a structure of a solid-state imaging device according to a second modification of the first embodiment.

FIG. 7 is a cross-sectional view illustrating a structure of a solid-state imaging device according to a third modification of the first embodiment.

FIG. 8 is a cross-sectional view illustrating a structure of a solid-state imaging device according to a fourth modification of the first embodiment.

FIG. 9 is a graph for explaining an operation of the solid-state imaging device of the first embodiment.

FIG. 10 is another graph for explaining an operation of the solid-state imaging device of the first embodiment.

FIG. 11 is a circuit diagram illustrating a configuration of a solid-state imaging device of a second embodiment.

FIG. 12 is a graph for explaining an operation of the solid-state imaging device according to the second embodiment.

FIG. 13 is a graph for explaining an operation of a solid-state imaging device of a third embodiment.

FIG. 14 is a cross-sectional view illustrating a structure of a solid-state imaging device according to a fourth embodiment.

FIG. 15 is a cross-sectional view illustrating a structure of a solid-state imaging device according to a fifth embodiment.

FIG. 16 is a cross-sectional view illustrating a structure of a solid-state imaging device of a sixth embodiment.

FIG. 17 is a cross-sectional view illustrating a structure of a solid-state imaging device according to a seventh embodiment.

FIG. 18 is a cross-sectional view illustrating a structure of a solid-state imaging device of an eighth embodiment.

FIG. 19 is a cross-sectional view illustrating a structure of a solid-state imaging device according to a ninth embodiment.

FIG. 20 is a plan view illustrating a structure of a solid-state imaging device according to a tenth embodiment.

FIG. 21 is a plan view illustrating a structure of a solid-state imaging device according to an eleventh embodiment.

FIG. 22 is a plan view illustrating a structure of a solid-state imaging device according to a twelfth embodiment.

FIG. 23 is a circuit diagram illustrating a configuration of a solid-state imaging device of a thirteenth embodiment.

FIG. 24 is a cross-sectional view illustrating a structure of a solid-state imaging device according to a fourteenth embodiment.

FIG. 25 is a graph for explaining an operation of the solid-state imaging device according to the fourteenth embodiment.

FIG. 26 is a perspective view illustrating a structure of a solid-state imaging device according to a fifteenth embodiment.

FIG. 27 is a block diagram illustrating a configuration of the solid-state imaging device according to the fifteenth embodiment.

FIG. 28 is a block diagram illustrating a configuration example of an electronic device.

FIG. 29 is a block diagram illustrating a configuration example of a mobile body control system.

FIG. 30 is a plan view illustrating a specific example of a setting position of an imaging unit in FIG. 29.

FIG. 31 is a diagram illustrating an example of a schematic configuration of an endoscopic surgery system.

FIG. 32 is a block diagram illustrating an example of functional configurations of a camera head and a CCU.

### MODE FOR CARRYING OUT THE INVENTION

Hereinafter, embodiments of the present disclosure will be described with reference to the drawings.

### First Embodiment

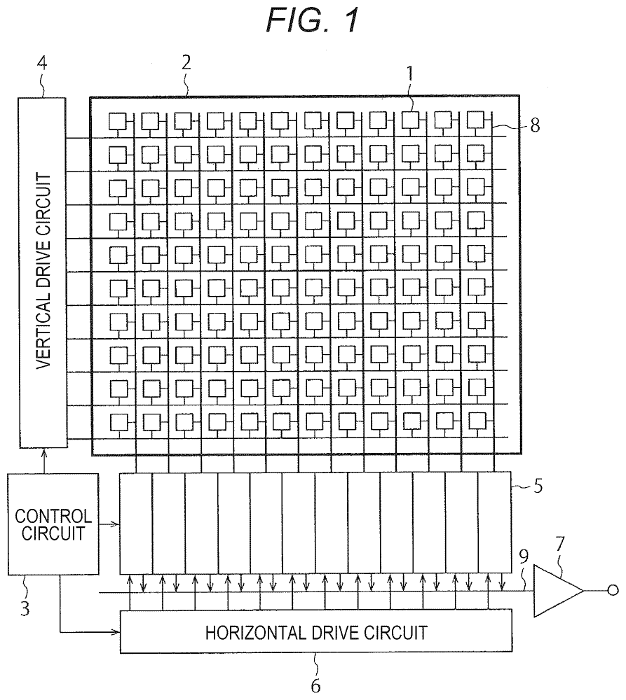

FIG. 1 is a block diagram illustrating a configuration of a solid-state imaging device of a first embodiment.

The solid-state imaging device in FIG. 1 is a complementary metal oxide semiconductor (CMOS) type image sensor (CIS), and includes a pixel array region 2 including a plurality of pixels 1, a control circuit 3, a vertical drive circuit 4, a plurality of column signal processing circuits 5, a horizontal drive circuit 6, an output circuit 7, a plurality of vertical signal lines (VSL) 8, and a horizontal signal line (HSL) 9.

Each of the pixels 1 includes a photodiode functioning as a photoelectric conversion unit and a MOS transistor functioning as a pixel transistor. Examples of the pixel transistor include a transfer transistor, a reset transistor, an amplification transistor, a selection transistor, and the like. These pixel transistors may be shared by several pixels 1.

The pixel array region 2 includes the plurality of the pixels 1 arranged in a two-dimensional array. The pixel array region 2 includes an effective pixel region that receives light, performs photoelectric conversion, and outputs a signal charge generated by the photoelectric conversion, and a black reference pixel region that outputs optical black serving as a reference of a black level. In general, the black reference pixel region is arranged on an outer peripheral portion of the effective pixel region.

The control circuit 3 generates various signals serving as references of operations of the vertical drive circuit 4, the column signal processing circuit 5, the horizontal drive circuit 6, and the like on the basis of a vertical synchronization signal, a horizontal synchronization signal, a master clock, and the like. The signals generated by the control circuit 3 are, for example, a clock signal and a control signal, and are input to the vertical drive circuit 4, the column signal processing circuit 5, the horizontal drive circuit 6, and the like.

The vertical drive circuit 4 includes, for example, a shift register, and scans each of the pixels 1 in the pixel array region 2 in the vertical direction row by row. The vertical drive circuit 4 further supplies a pixel signal based on the signal charge generated by each pixel 1 to the column signal processing circuits 5 through the vertical signal lines 8.

Each of the column signal processing circuits 5 is arranged, for example, for every column of the pixels 1 in the pixel array region 2, and performs signal processing of the signals output from the pixels 1 of one row for every column on the basis of a signal from the black reference pixel region. Examples of this signal processing are noise removal and signal amplification.

The horizontal drive circuit 6 includes, for example, a shift register, and supplies the pixel signal from each of the column signal processing circuits 5 to the horizontal signal line 9.

The output circuit 7 performs signal processing on the signal supplied from each of the column signal processing circuits 5 through the horizontal signal line 9, and outputs the signal subjected to the signal processing.

Note that the pixel array region 2 of the present embodiment may include only one of the pixel 1 that detects visible light and the pixel 1 that detects light other than visible light, or may include both the pixel 1 that detects visible light and the pixel 1 that detects light other than visible light. The light other than the visible light is, for example, infrared light.

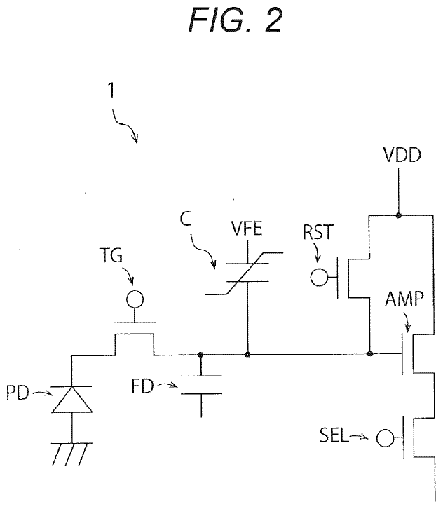

FIG. 2 is a circuit diagram illustrating a configuration of the solid-state imaging device of the first embodiment.

As illustrated in FIG. 2, each pixel 1 includes a photodiode PD, a floating diffusion portion FD, a ferroelectric capacitor C, a transfer transistor TG, a reset transistor RST, an amplification transistor AMP, and a selection transistor SEL.

The photodiode PD performs photoelectric conversion of incident light. An anode of the photodiode PD is electrically connected to the ground potential, and a cathode of the photodiode PD is electrically connected to the transfer transistor TG. Incident light into the photodiode PD is referred to as exposure of the photodiode PD.

The transfer transistor TG transfers a charge generated by the above-described photoelectric conversion to the floating diffusion portion FD. One of a source and a drain of the transfer transistor TG is electrically connected to the photodiode PD, and the other of the source and the drain of the transfer transistor TG is electrically connected to the floating diffusion portion FD, the ferroelectric capacitor C, the reset transistor RST, and the amplification transistor AMP.

The floating diffusion portion FD accumulates charges transferred by the transfer transistor TG. As illustrated in FIG. 2, the floating diffusion portion FD functions as a capacitor. The floating diffusion portion FD is electrically connected to the transfer transistor TG, the ferroelectric capacitor C, the reset transistor RST, and the amplification transistor AMP.

The reset transistor RST discharges charges from the floating diffusion portion FD and resets a potential of the floating diffusion portion FD to a power supply voltage (VDD) before the exposure of the photodiode PD is started. One of a source and a drain of the reset transistor RST is electrically connected to the power supply voltage, and the other of the source and the drain of the reset transistor RST is electrically connected to the transfer transistor TG, the floating diffusion portion FD, the ferroelectric capacitor C, and the amplification transistor AMP.

The amplification transistor AMP receives the charges transferred to the floating diffusion portion FD at a gate, and outputs the charges to the vertical signal line 8 by a source follower. The gate of the amplification transistor AMP is electrically connected to the transfer transistor TG, the floating diffusion portion FD, the ferroelectric capacitor C, and the reset transistor RST. One of a source and a drain of the amplification transistor AMP is electrically connected to the power supply voltage, and the other of the source and the drain of the amplification transistor AMP is electrically connected to the selection transistor SEL.

The selection transistor SEL can electrically connect the amplification transistor AMP and the vertical signal line 8. When the selection transistor SEL is turned on, the amplification transistor AMP and the vertical signal line 8 are electrically connected, and when the selection transistor SEL is turned off, the amplification transistor AMP and the vertical signal line 8 are electrically insulated. One of a source and a drain of the selection transistor SEL is electrically connected to the amplification transistor AMP, and the other of the source and the drain of the selection transistor SEL is electrically connected or connectable to the vertical signal line 8.

The ferroelectric capacitor C is connected in parallel with the floating diffusion portion FD. One electrode of the ferroelectric capacitor C is electrically connected to the transfer transistor TG, the floating diffusion portion FD, the reset transistor RST, and the amplification transistor AMP, and corresponds to an example of the first electrode of the present disclosure. The other electrode of the ferroelectric capacitor C is electrically connected to a wiring that supplies a voltage VFE, and corresponds to an example of the second electrode of the present disclosure. The ferroelectric capacitor C includes a ferroelectric film between these electrodes.

Note that, as illustrated in FIG. 2, each pixel 1 of the present embodiment does not include a switch transistor between the floating diffusion portion FD and the ferroelectric capacitor C.

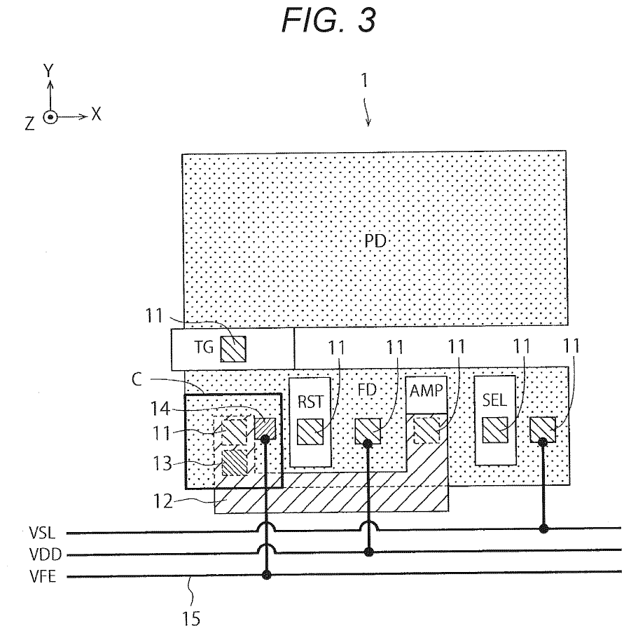

FIG. 3 is a plan view illustrating a structure of the solid-state imaging device of the first embodiment.

FIG. 3 illustrates an X axis, a Y axis, and a Z axis perpendicular to each other. An X direction and a Y direction correspond to a lateral direction (horizontal direction), and a Z direction corresponds to a longitudinal direction (vertical direction). Furthermore, a +Z direction corresponds to an upward direction, and a −Z direction corresponds to a downward direction. Note that the −Z direction may strictly match the gravity direction, or does not necessarily strictly match the gravity direction.

As illustrated in FIG. 3, each pixel 1 includes the photodiode PD, the floating diffusion portion FD, the ferroelectric capacitor C, the transfer transistor TG, the reset transistor RST, the amplification transistor AMP, and the selection transistor SEL. The functions and circuit configurations of these constituent elements are as described with reference to FIG. 2.

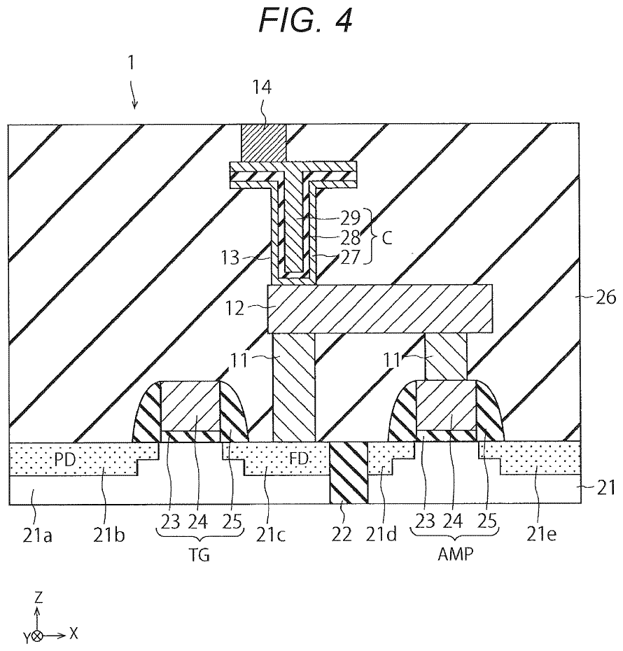

FIG. 3 further schematically illustrates a VSL wiring (vertical signal line 8), a VDD wiring, and a VFE wiring. FIG. 3 further illustrates a plurality of contact plugs 11, a wiring 12, a contact hole 13, a wiring 14, and a wiring 15. Some of these constituent elements are also illustrated in FIG. 4 described below.

The contact plugs 11 are provided on the floating diffusion portion FD, the transfer transistor TG, the reset transistor RST, the amplification transistor AMP, and the selection transistor SEL. The wiring 12 is provided on the contact plug 11 located on the floating diffusion portion FD and on the contact plug 11 located on the amplification transistor AMP, and electrically connects the floating diffusion portion FD and the amplification transistor AMP. Therefore, the floating diffusion portion FD is equipotential to the gate of the amplification transistor AMP. Further details of the contact plugs 11 and the wiring 12 will be described later with reference to FIG. 4.

The contact hole 13 is provided on the wiring 12. A part of the ferroelectric capacitor C is embedded in the contact hole 13 and is electrically connected to the wiring 12 in the contact hole 13. The wiring 14 is provided on the ferroelectric capacitor C and is electrically connected to the ferroelectric capacitor C. Further details of the contact hole 13 and the wiring 14 will be described later.

The wiring 15 is the VFE wiring illustrated in FIG. 3, and is electrically connected to the electrode of the ferroelectric capacitor C via the wiring 14. The wiring 15 can supply the voltage VFE described above to this electrode, thereby controlling the potential of this electrode.

Note that FIG. 3 illustrates a layout of a front-illuminated solid-state imaging device, but the solid-state imaging device of the present embodiment may be a back-illuminated type. As a result, an area of the photodiode (PD) region can be effectively used, and a region where the ferroelectric capacitor C can be formed can be increased.

FIG. 4 is a cross-sectional view illustrating a structure of the solid-state imaging device of the first embodiment. Similarly to FIGS. 2 and 3, FIG. 4 illustrates one pixel 1 in the solid-state imaging device of the present embodiment. In FIG. 4, for clarity of explanation, constituent element degrees that do not exist in the same XZ plane in FIG. 3 are also illustrated in the same XZ cross section.

As illustrated in FIG. 4, the solid-state imaging device of the present embodiment includes the contact plug 11, the wiring 12, the contact hole 13, and the wiring 14. The solid-state imaging device according to the present embodiment further includes: a substrate 21; an element isolation insulating film 22; a gate insulating film 23, a gate electrode 24, and a sidewall insulating film 25 included in the transfer transistor TG and the amplification transistor AMP; an interlayer insulating film 26; and an electrode 27, a ferroelectric film 28, and an electrode 29 included in the ferroelectric capacitor C. The substrate 21 is an example of the first substrate of the present disclosure. The electrode 27 is an example of the first electrode of the present disclosure. The electrode 29 is an example of the second electrode of the present disclosure.

The substrate 21 is, for example, a semiconductor substrate such as a silicon substrate. In FIG. 4, the X direction and the Y direction are parallel to an upper surface of the substrate 21, and the Z direction is perpendicular to the upper surface of the substrate 21. The substrate 21 includes a well region 21a and diffusion regions 21b, 21c, 21d, and 21e. The diffusion regions 21b and 21c function as source and drain regions of the transfer transistor TG, and the diffusion regions 21d and 21e function as source and drain regions of the amplification transistor AMP. Furthermore, the photodiode PD is formed by a pn junction between the well region 21a and the diffusion region 21b, or the like. Furthermore, the diffusion region 21c also functions as the floating diffusion portion FD.

The element isolation insulating film 22 is formed in the substrate 21. The element isolation insulating film 22 is, for example, a silicon oxide film. The element isolation insulating film 22 illustrated in FIG. 4 is interposed between the transfer transistor TG and the amplification transistor AMP.

In each of the transfer transistor TG and the amplification transistor AMP, the gate insulating film 23 is formed on the substrate 21, the gate electrode 24 is formed on the gate insulating film 23, and the sidewall insulating film 25 is formed on a side surface of the gate electrode 24. In the present embodiment, each of the reset transistor RST and the selection transistor SEL also includes the gate insulating film 23, the gate electrode 24, and the sidewall insulating film 25.

The interlayer insulating film 26 is formed on the substrate 21 so as to cover the transfer transistor TG and the amplification transistor AMP. In the present embodiment, the reset transistor RST and the selection transistor SEL are also covered with the interlayer insulating film 26.

The contact plug 11, the wiring 12, the contact hole 13, and the wiring 14 are formed in the interlayer insulating film 26 on the substrate 21. FIG. 4 illustrates the contact plug 11 provided on the floating diffusion portion FD and the contact plug 11 provided on the gate electrode 24 of the amplification transistor AMP. The wiring 12 is provided on these contact plugs 11, and electrically connects the floating diffusion portion FD and the amplification transistor AMP.

The contact hole 13 is provided on the wiring 12. A part of the ferroelectric capacitor C is embedded in the contact hole 13 and is electrically connected to the wiring 12 in the contact hole 13. The wiring 14 is provided on the ferroelectric capacitor C and is electrically connected to the ferroelectric capacitor C.

The ferroelectric capacitor C includes the electrode 27, the ferroelectric film 28, and the electrode 29 which are sequentially formed inside and outside the contact hole 13. Inside the contact hole 13, the electrode 27, the ferroelectric film 28, and the electrode 29 are sequentially formed on an upper surface of the wiring 12 and a side surface of the interlayer insulating film 26. Outside the contact hole 13, the electrode 27, the ferroelectric film 28, and the electrode 29 are sequentially formed on an upper surface of the interlayer insulating film 26. The electrode 27 is in contact with the upper surface of the wiring 12 and is electrically connected to the wiring 12. The electrode 29 is in contact with a lower surface of the wiring 14 and is electrically connected to the wiring 14. As described above, the ferroelectric capacitor C of the present embodiment has a three-dimensional structure spreading in the X direction, the Y direction, and the Z direction.

The ferroelectric film 28 desirably contains, for example, hafnium (Hf), zirconium (Zr), niobium (Nb), scandium (Sc), yttrium (Y), lanthanum (La), germanium (Ge), or silicon (Si). Examples of the ferroelectric film 28 according to the present embodiment include a hafnium oxide (HfO₂) film, a lead zirconate titanate (PZT) film, a strontium bismuth tantalate (SBT) film, and a lanthanum bismuth titanate (BLT) film. On the other hand, each of the electrodes 27 and 29 desirably includes a metal having high reducibility, such as a laminated film including a TiN film and a TiAl film, or a laminated film including a TiN film, a TaN film, and a TiAl film (Ti, N, Al, and Ta represent titanium, nitrogen, aluminum, and tantalum, respectively).

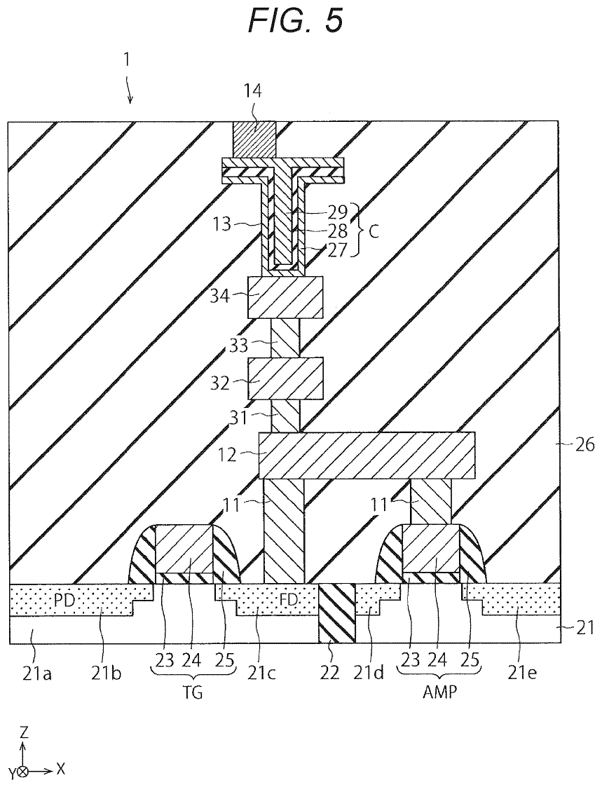

The solid-state imaging device of the present embodiment may have a structure illustrated in any of FIGS. 5 to 8 instead of having the structure illustrated in FIG. 4.

FIG. 5 is a cross-sectional view illustrating a structure of a solid-state imaging device according to a first modification of the first embodiment.

The solid-state imaging device of the present modification includes a via plug 31, a wiring 32, a via plug 33, and a wiring 34 which are sequentially formed on the wiring 12 in addition to the constituent elements illustrated in FIG. 4. In the present modification, the ferroelectric capacitor C is formed on the wiring 34. As described above, the ferroelectric capacitor C may be formed on the wiring (wiring 12) in a lowermost wiring layer as illustrated in FIG. 4, or may be formed on the wiring (wiring 34) in another wiring layer as illustrated in FIG. 5. In FIG. 5, the wirings 12, 32, and 34 are located in the first (lowermost) wiring layer, the second wiring layer, and the third wiring layer, respectively.

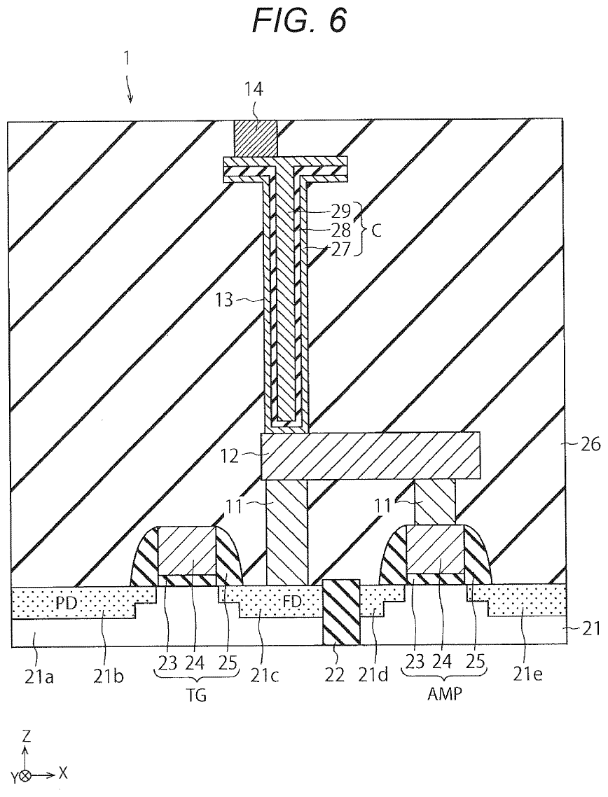

FIG. 6 is a cross-sectional view illustrating a structure of a solid-state imaging device according to a second modification of the first embodiment.

The contact hole 13 of the present modification has a shape elongated in the Z direction and penetrates one or more wiring layers. As described above, the contact hole 13 may have a shape that does not penetrate the wiring layer as illustrated in FIG. 4, or may have a shape that penetrates one or more wiring layers as illustrated in FIG. 6.

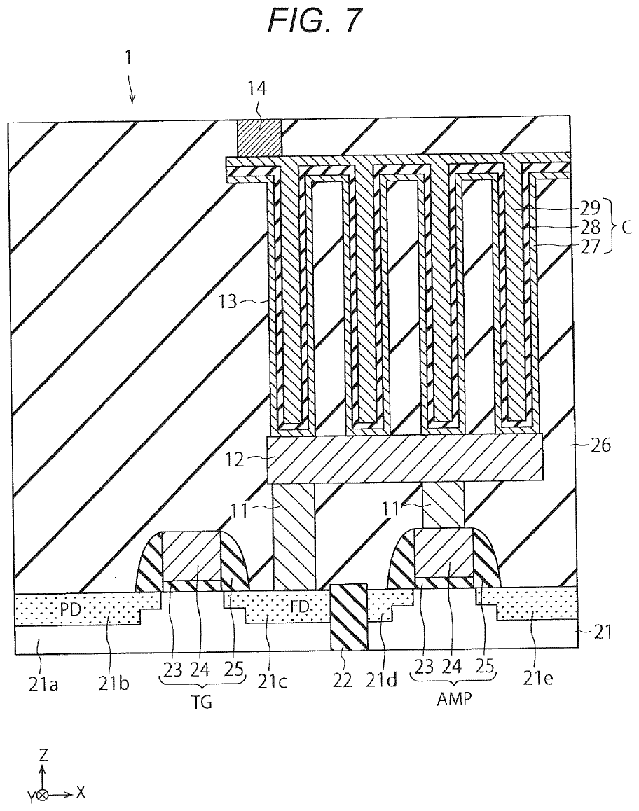

FIG. 7 is a cross-sectional view illustrating a structure of a solid-state imaging device according to a third modification of the first embodiment.

The ferroelectric capacitor C of the present modification is formed in two or more contact holes 13. In each contact hole 13, the electrode 27, the ferroelectric film 28, and the electrode 29 are sequentially formed on the upper surface of the wiring 12 and the side surface of the interlayer insulating film 26. In FIG. 7, the ferroelectric capacitor C includes four partial capacitors formed in the four contact holes 13, and these partial capacitors are connected in parallel. Note that a contact area between these partial capacitors and the wiring 12 is desirably as wide as possible.

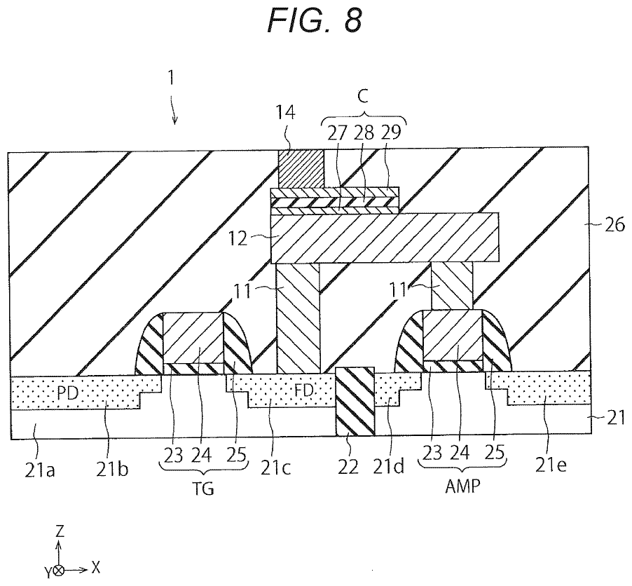

FIG. 8 is a cross-sectional view illustrating a structure of a solid-state imaging device according to a fourth modification of the first embodiment.

The ferroelectric capacitor C of the present modification does not include a portion formed in the contact hole 13, and has a two-dimensional structure having expansion in the X direction and the Y direction. That is, the ferroelectric capacitor C of the present modification is a parallel plate capacitor including the planar electrode 27, the ferroelectric film 28, and the electrode 29. As described above, the ferroelectric capacitor C may have a three-dimensional structure as illustrated in FIG. 4, or may have a two-dimensional structure as illustrated in FIG. 8.

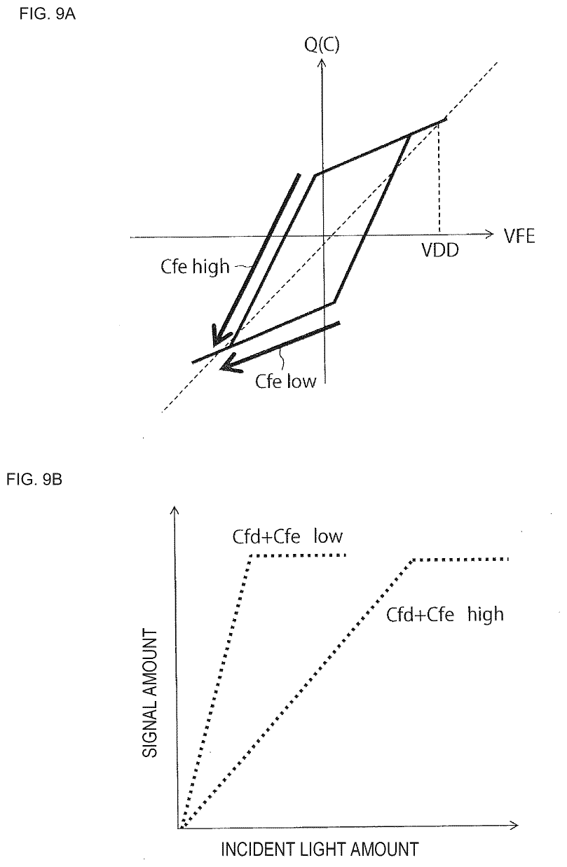

FIG. 9 is a graph for explaining an operation of the solid-state imaging device of the first embodiment.

A of FIG. 9 illustrates a Q-V curve for explaining an operation of the ferroelectric capacitor C of the present embodiment. The horizontal axis in A of FIG. 9 represents a potential (voltage VFE) applied to the ferroelectric capacitor C. The vertical axis in A of FIG. 9 represents a polarization amount generated in the ferroelectric capacitor C. When a direction of a write voltage applied to the ferroelectric capacitor C changes, residual polarization occurs in the ferroelectric capacitor C. Therefore, the Q-V curve of the ferroelectric capacitor C draws hysteresis as illustrated in A of FIG. 9. Furthermore, a capacitance Cfe of the ferroelectric capacitor C represented by the slope of the Q-V curve can take two types of values Cfe low and Cfe high as illustrated in A of FIG. 9. The Q-V curve illustrated in A of FIG. 9 has a shape close to a parallelogram. Cfe low corresponds to the inclination of a lower side of the parallelogram, and Cfe high corresponds to the inclination of a left side of the parallelogram.

The conversion efficiency ΔV of photoelectric conversion by the photodiode PD of the present embodiment is expressed by the following Formula (1).

ΔV=Q/(Cfd+Cfe) (1)

Note that Q represents an amount of electric charges generated by photoelectric conversion and transferred to the floating diffusion portion FD, and Cfd represents the capacitance of the floating diffusion portion FD. Therefore, Cfd+Cfe represents a sum (combined capacitance) of the capacitance Cfd of the floating diffusion portion FD and the capacitance Cfe of the ferroelectric capacitor C. As can be seen from Formula (1), the conversion efficiency ΔV depends on the combined capacitance Cfd+Cfe, and is specifically inversely proportional to the combined capacitance Cfd+Cfe.

In Formula (1), the capacitance Cfe of the ferroelectric capacitor C corresponds to a capacitance added to the capacitance Cfd of the floating diffusion portion FD. The capacitance of each pixel 1 of the present embodiment includes not only the capacitance Cfd of the floating diffusion portion FD but also the capacitance Cfe of the ferroelectric capacitor C added to the capacitance Cfd of the floating diffusion portion FD.

In the solid-state imaging device according to the present embodiment, the state of the ferroelectric capacitor C is set to either the “Cfe low state” or the “Cfe high state” in advance before reading from the floating diffusion portion FD. That is, before reading from the floating diffusion portion FD, the capacitance Cfe of the ferroelectric capacitor C is Cfe low or Cfe high. As a result, the conversion efficiency ΔV can be switched to two types of values, and the dynamic range of the solid-state imaging device can be improved by such switching. For example, the dynamic range can be improved by setting the conversion efficiency ΔV at low illuminance and the conversion efficiency ΔV at high illuminance to different values. The state of the ferroelectric capacitor C is controlled by, for example, the control circuit 3.

In a case where the ferroelectric capacitor C of the present embodiment is replaced with a paraelectric capacitor, a capacitance Cpe of the paraelectric capacitor cannot be changed like the capacitance Cfe of the ferroelectric capacitor C. In this case, when a switch transistor is disposed between the floating diffusion portion FD and the paraelectric capacitor, the conversion efficiency ΔV can be switched to two types of values by switching on and off of the switch transistor. This is because the combined capacitance in a case where the switch transistor is off is Cfd, and the combined capacitance when the switch transistor is on is Cfd+Cpe. However, when the switch transistor is disposed in the solid-state imaging device, the area efficiency of the solid-state imaging device is deteriorated, and the manufacturing process of the solid-state imaging device becomes complicated. On the other hand, according to the present embodiment, since the conversion efficiency ΔV can be switched without using the switch transistor, such a problem can be solved.

B of FIG. 9 illustrates a relationship between a signal amount and an incident light amount in the solid-state imaging device of the present embodiment. Specifically, B of FIG. 9 illustrates the relationship between the signal amount and the incident light amount in a case where the combined capacitance is “Cfd+Cfe low” and a case where the combined capacitance is “Cfd+Cfe high”. According to the present embodiment, since a state having two types of sensitivity can be realized, it is possible to improve the dynamic range.

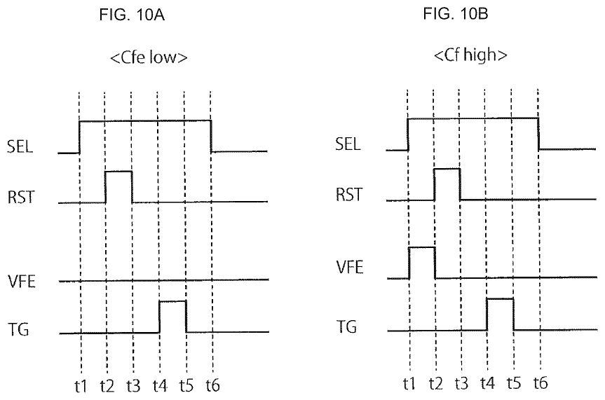

FIG. 10 is another graph for explaining an operation of the solid-state imaging device of the first embodiment.

A of FIG. 10 illustrates an operation of the selection transistor SEL, an operation of the reset transistor RST, a change in the voltage VFE, and an operation of the transfer transistor TG in a Cfe low state. B of FIG. 10 illustrates an operation of the selection transistor SEL, an operation of the reset transistor RST, a change in the voltage VFE, and an operation of the transfer transistor TG in a Cfe high state. Reference signs t1 to t6 indicate time.

In the present embodiment, a difference between the voltage VFE and the voltage VDD is used to set the state of the ferroelectric capacitor C to the “Cfe low state” or the “Cfe high state”. Specifically, the state of the ferroelectric capacitor C is set before the charges from the photodiode PD are transferred with the transfer transistor TG turned on.

For example, in a case where it is desired to set the state of the ferroelectric capacitor C to the “Cfe low state” (A of FIG. 10), the voltage VFE is set to 0 V, and the reset transistor RST is turned on. As a result, a potential of the electrode 27 (lower electrode) electrically connected to the floating diffusion portion FD becomes higher than a potential of the electrode 29 (upper electrode) electrically connected to the VFE wiring, and the state of the ferroelectric capacitor C becomes the “Cfe low state”.

On the other hand, in a case where it is desired to set the state of the ferroelectric capacitor C to the “Cfe high state” (B of FIG. 10), the voltage VFE is set higher than the voltage VDD, and the reset transistor RST is turned on. As a result, the potential of the electrode 27 (lower electrode) electrically connected to the floating diffusion portion FD becomes lower than the potential of the electrode 29 (upper electrode) electrically connected to the VFE wiring, and the state of the ferroelectric capacitor C becomes the “Cfe high state”.

As described above, the solid-state imaging device according to the present embodiment includes the ferroelectric capacitor C electrically connected to the floating diffusion portion FD. Therefore, according to the present embodiment, it is possible to suitably form the capacitor for the floating diffusion portion FD, for example, to improve the dynamic range without using the switch transistor.

### Second Embodiment

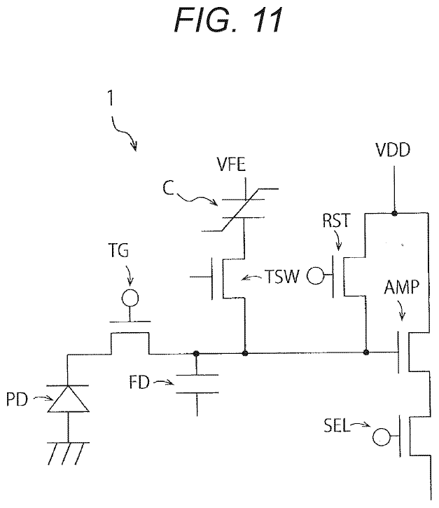

FIG. 11 is a circuit diagram illustrating a configuration of a solid-state imaging device of a second embodiment.

Similarly to FIG. 2, FIG. 11 illustrates one pixel 1 in the solid-state imaging device illustrated in FIG. 1. Each pixel 1 (FIG. 11) of the present embodiment includes a switch transistor TSW in addition to the constituent elements illustrated in FIG. 2.

One of a source and a drain of the switch transistor TSW is electrically connected to a ferroelectric capacitor C, and the other of the source and the drain of the switch transistor TSW is electrically connected to a transfer transistor TG, a floating diffusion portion FD, a reset transistor RST, and an amplification transistor AMP. Therefore, the ferroelectric capacitor C of the present embodiment can be electrically connected to the transfer transistor TG, the floating diffusion portion FD, the reset transistor RST, and the amplification transistor AMP by applying a predetermined voltage to a gate of the switch transistor TSW to turn on the switch transistor TSW. In this case, the ferroelectric capacitor C of the present embodiment is electrically connected to the transfer transistor TG, the floating diffusion portion FD, the reset transistor RST, and the amplification transistor AMP via the switch transistor TSW.

For example, the switch transistor TSW may include a gate insulating film 23, a gate electrode 24, a sidewall insulating film 25, and the like on a substrate 21, similarly to the transfer transistor TG and the like illustrated in FIG. 4. Furthermore, the switch transistor TSW may be formed in other modes, and may be formed as a thin film transistor in an interlayer insulating film 26, for example.

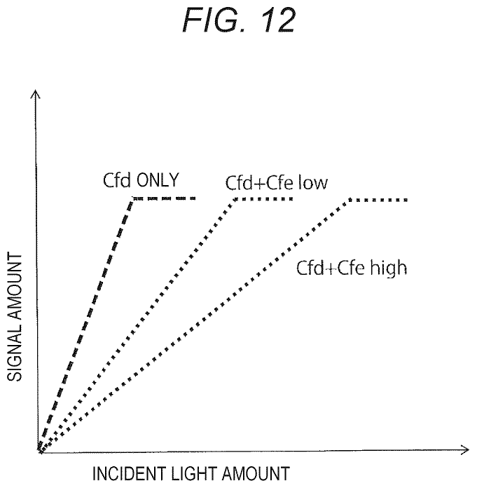

FIG. 12 is a graph for explaining an operation of the solid-state imaging device of the second embodiment.

Similarly to B of FIG. 9, FIG. 12 illustrates a relationship between a signal amount and an incident light amount in the solid-state imaging device of the present embodiment. The combined capacitance of the floating diffusion portion FD and the ferroelectric capacitor C of the present embodiment can be switched to three types of values “Cfd”, “Cfd+Cfe low”, and “Cfd+Cfe high” by using the hysteresis of the ferroelectric capacitor C and on/off of the switch transistor TSW. For example, when the switch transistor TSW is turned off, the combined capacitance becomes Cfd. Furthermore, when the switch transistor TSW is turned on and the state of the ferroelectric capacitor C is set to the “Cfe low state”, the combined capacitance becomes Cfd+Cfe low. Furthermore, when the switch transistor TSW is turned on and the state of the ferroelectric capacitor C is set to the “Cfe high state”, the combined capacitance becomes Cfd+Cfe high. The state of the ferroelectric capacitor C and on/off of the switch transistor TSW are controlled by, for example, the control circuit 3.

As described above, the solid-state imaging device according to the present embodiment includes the ferroelectric capacitor C electrically connectable to the floating diffusion portion FD via the switch transistor TSW. Therefore, according to the present embodiment, although it is necessary to dispose the switch transistor TSW, the conversion efficiency ΔV can be switched to three types of values, and the dynamic range of the solid-state imaging device can be further improved by such switching.

According to the present embodiment, as illustrated in FIG. 12, exposure having three-stage sensitivity can be performed. Note that the combined capacitance of the floating diffusion portion FD and the ferroelectric capacitor C of the present embodiment may be switched to four or more types of values. As a result, exposure having sensitivity of four or more stages can be performed, and the dynamic range of the solid-state imaging device can be further improved.

### Third Embodiment

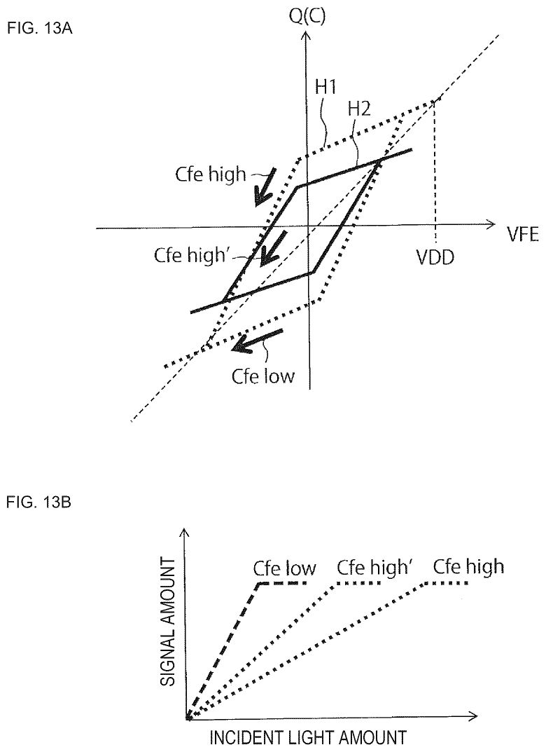

FIG. 13 is a graph for explaining an operation of a solid-state imaging device of a third embodiment.

Similarly to A of FIG. 9, A of FIG. 13 illustrates a Q-V curve for explaining an operation of the ferroelectric capacitor C of the present embodiment. The solid-state imaging device of the present embodiment has the configurations and structures illustrated in FIGS. 1 to 4, similarly to the solid-state imaging device of the first embodiment.

A ferroelectric capacitor C of the present embodiment exhibits different Q-V curves by setting a voltage VFE to different values. In A of FIG. 13, a curve H1 indicates a Q-V curve in a case where the voltage VFE has a first value, and a curve H2 indicates a Q-V curve in a case where the voltage VFE has a second value. The curve H1 is the same Q-V curve as the Q-V curve illustrated in A of FIG. 9.

The curve H2 has a shape close to a parallelogram similarly to the curve H1, but has a shape different from the curve H1. In A of FIG. 13, Cfe low corresponds to the inclination of a lower side of the curve H1, Cfe high corresponds to the inclination of a left side of the curve H1, and Cfe high′ corresponds to the inclination of a left side of the curve H2. Therefore, Cfe high′ is a value larger than Cfe low and smaller than Cfe high.

B of FIG. 13 illustrates a relationship between a signal amount and an incident light amount in the solid-state imaging device of the present embodiment, similarly to B of FIG. 9. The combined capacitance of a floating diffusion portion FD and the ferroelectric capacitor C of the present embodiment can be switched to three types of values “Cfd+Cfe low”, “Cfd+Cfe high”, and “Cfd+Cfe high′” by using the hysteresis of the ferroelectric capacitor C and the adjustment of the voltage VFE applied to the ferroelectric capacitor C. For example, when the voltage VFE is adjusted to the first value and the state of the ferroelectric capacitor C is set to the “Cfe low state”, the combined capacitance becomes Cfd+Cfe low. Furthermore, when the voltage VFE is adjusted to the first value and the state of the ferroelectric capacitor C is set to the “Cfe high state”, the combined capacitance becomes Cfd+Cfe high. Furthermore, when the voltage VFE is adjusted to the second value and the state of the ferroelectric capacitor C is set to the “Cfe high′ state”, the combined capacitance becomes Cfd+Cfe high′. The state of the ferroelectric capacitor C and the value of the voltage VFE are controlled by, for example, the control circuit 3.

As described above, the solid-state imaging device according to the present embodiment changes the Q-V curve of the ferroelectric capacitor C by changing the voltage VFE to the value. Therefore, according to the present embodiment, the conversion efficiency ΔV can be switched to three types of values, and the dynamic range of the solid-state imaging device can be further improved by such switching.

According to the present embodiment, as illustrated in B of FIG. 13, exposure having three-stage sensitivity can be performed. Note that the combined capacitance of the floating diffusion portion FD and the ferroelectric capacitor C of the present embodiment may be switched to four or more types of values. As a result, exposure having sensitivity of four or more stages can be performed, and the dynamic range of the solid-state imaging device can be further improved. For example, exposure having four-stage sensitivity may be performed by using not only the inclination (Cfe high′) of the left side of the curve H2 but also the inclination of the lower side of the curve H2. Furthermore, exposure having sensitivity of four or more stages may be performed by switching the voltage VFE to three or more different values. Furthermore, not only the left side or the lower side of the Q-V curve but also a right side or an upper side of the Q-V curve may be used.

### Fourth Embodiment

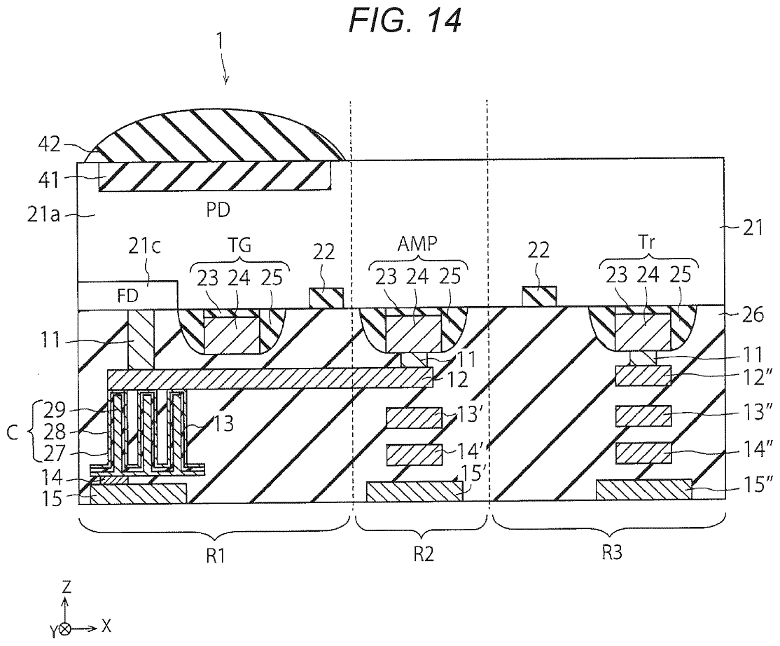

FIG. 14 is a cross-sectional view illustrating a structure of a solid-state imaging device according to a fourth embodiment. Similarly to FIG. 4, FIG. 14 illustrates one pixel 1 and the like in the solid-state imaging device of the present embodiment.

In FIG. 14, a lower surface of a substrate 21 is a front surface of the substrate 21, and an upper surface of the substrate 21 is a back surface of the substrate 21. The solid-state imaging device according to the present embodiment is a back-illuminated type, and the upper surface (back surface) of the substrate 21 is a light incident surface (light-receiving surface) of the substrate 21. In FIG. 14, the lower surface of the substrate 21 is an example of the first surface of the present disclosure, and the upper surface of the substrate 21 is an example of the second surface of the present disclosure.

The solid-state imaging device of the present embodiment includes a photodiode region R1, a pixel transistor region R2, and a logic circuit region R3 as regions existing in the substrate 21, on the substrate 21, and under the substrate 21. Portions under the substrate 21 of the photodiode region R1, the pixel transistor region R2, and the logic circuit region R3 are examples of the first region, the second region, and the third region of the present disclosure, respectively.

The photodiode region R1 includes a photodiode PD, a floating diffusion portion FD, a transfer transistor TG, and the like. The photodiode region R1 illustrated in FIG. 14 corresponds to one pixel 1 in the solid-state imaging device of the present embodiment. The photodiode region R1 further includes an on-chip filter 41 formed on the upper surface side of the substrate 21 and an on-chip lens 42 formed on the on-chip filter 41. The photodiode region R1 further includes a ferroelectric capacitor C formed on the lower surface side of the substrate 21.

The on-chip filter 41 has a function of transmitting light having a predetermined wavelength, and is formed on the upper surface of the substrate 21 for each pixel 1. For example, the on-chip filters 41 for red (R), green (G), and blue (B) are arranged above the photodiodes PD of the red, green, and blue pixels 1, respectively. Moreover, the on-chip filter 41 for infrared light may be arranged above the photodiode PD of the pixel 1 of infrared light.

The on-chip lens 42 has a function of condensing incident light, and is formed on the on-chip filter 41 for each pixel 1. In the present embodiment, light incident on the on-chip lens 42 is condensed by the on-chip lens 42, transmitted through the on-chip filter 41, and incident on the photodiode PD. The photodiode PD converts the light into a charge by photoelectric conversion to generate a signal charge.

The pixel transistor region R2 includes a pixel transistor other than the transfer transistor TG, and includes, for example, a reset transistor RST, an amplification transistor AMP, and a selection transistor SEL. FIG. 14 illustrates the amplification transistor AMP provided in the pixel transistor region R2.

The logic circuit region R3 includes a logic circuit of the solid-state imaging device of the present embodiment. FIG. 14 illustrates a transistor Tr constituting the logic circuit. Similarly to the transfer transistor TG and the amplification transistor AMP, the transistor Tr includes a gate insulating film 23, a gate electrode 24, and a sidewall insulating film 25.

The solid-state imaging device of the present embodiment includes, on the lower surface side of the substrate 21, a contact plug 11, a wiring 12, a contact hole 13, a wiring 14, a wiring 15, an element isolation insulating film 22, the gate insulating film 23, the gate electrode 24, and the sidewall insulating film 25 of each transistor, an interlayer insulating film 26, and an electrode 27, a ferroelectric film 28, and an electrode 29 of the ferroelectric capacitor C. The solid-state imaging device of the present embodiment further includes, in the pixel transistor region R2, a contact plug 11, a wiring 12 (common to the photodiode region R1), a wiring 13′, a wiring 14′, and a wiring 15′. The solid-state imaging device of the present embodiment further includes, in the logic region R3, a contact plug 11, a wiring 12″ and a wiring 13″, and a wiring 14″ and a wiring 15″. The wiring 12 and the wiring 12″ are located in the same wiring layer, and the wiring 13′ and the wiring 13″ are also located in the same wiring layer. Similarly, the wiring 14′ and the wiring 14″ are located in the same wiring layer, and the wiring 15, the wiring 15′, and the wiring 15″ are also located in the same wiring layer.

According to the present embodiment, by forming the transfer transistor TG, the other pixel transistors, and the logic circuit on the lower surface of the same substrate 21, the solid-state imaging device can be manufactured with a small number of steps. For example, even if the number of steps is increased by the amount for forming the ferroelectric capacitor C, the number of steps for forming other constituent elements can be reduced, so that the total number of steps for manufacturing the solid-state imaging device can be reduced.

### Fifth Embodiment

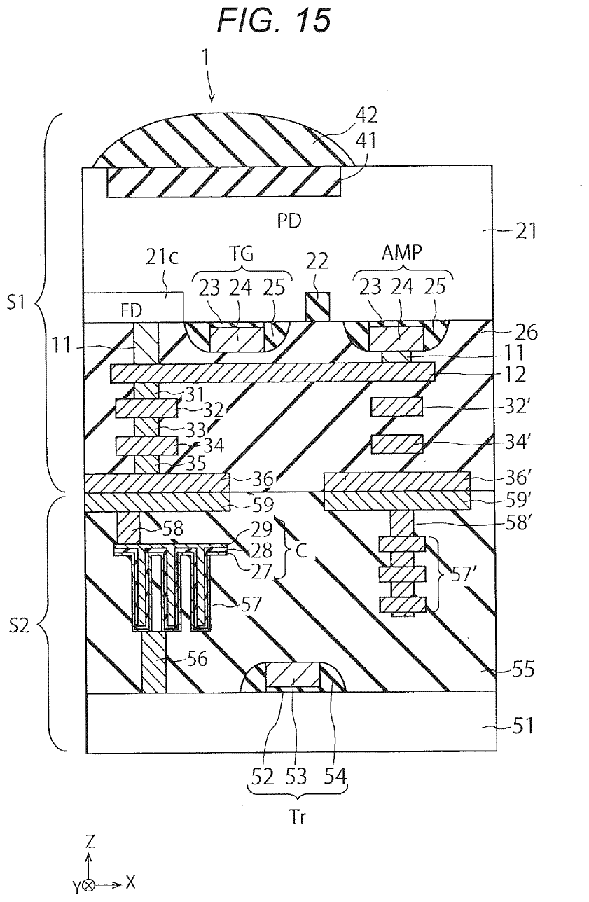

FIG. 15 is a cross-sectional view illustrating a structure of a solid-state imaging device of a fifth embodiment.

The solid-state imaging device of the present embodiment is a back-illuminated type, similarly to the solid-state imaging device of the fourth embodiment. However, the solid-state imaging device of the present embodiment has a two-layer structure including an upper layer S1 and a lower layer S2.

The upper layer S1 has a structure similar to that of the solid-state imaging device of the fourth embodiment. However, the upper layer S1 does not include the ferroelectric capacitor C, the transistor Tr, and the like, and instead includes a via plug 31, a wiring 32, a via plug 33, a wiring 34, a via plug 35, a wiring 36, a wiring 32′, a wiring 34′, and a wiring 36′. The via plug 31, the wiring 32, the via plug 33, the wiring 34, the via plug 35, and the wiring 36 are sequentially formed below a wiring 12 in an interlayer insulating film 26. The wirings 32′, 34′, and 36′ are located in the same wiring layer as the wirings 32, 34, and 36 in the interlayer insulating film 26, respectively.

The lower layer S2 includes a substrate 51, a gate insulating film 52, a gate electrode 53, and a sidewall insulating film 54 included in a transistor Tr, an interlayer insulating film 55, a contact plug 56, a contact hole 57, a via plug 58, a wiring 59, a multilayer wiring structure 57′, a via plug 58′, and a wiring 59′. The lower layer S2 further includes an electrode 27, a ferroelectric film 28, and an electrode 29 included in a ferroelectric capacitor C. The substrate 51 is an example of the second substrate of the present disclosure.

The substrate 51 is, for example, a semiconductor substrate such as a silicon substrate. The lower layer S2 includes a logic circuit on the substrate 51, and the transistor Tr illustrated in FIG. 15 constitutes a logic circuit similarly to the transistor Tr illustrated in FIG. 14. However, the transistor Tr illustrated in FIG. 15 includes not the gate insulating film 23, the gate electrode 24, and the sidewall insulating film 25 formed on the lower surface of the substrate 21 but the gate insulating film 52, the gate electrode 53, and the sidewall insulating film 54 formed on the upper surface of the substrate 21. As described above, the solid-state imaging device according to the present embodiment includes a photodiode region R1 and a pixel transistor region R2 in the upper layer S1, and includes a logic circuit region R3 in the lower layer S2.

The interlayer insulating film 55 is formed on the substrate 51 so as to cover the transistor Tr. An upper surface of the interlayer insulating film 55 is in contact with a lower surface of the interlayer insulating film 26. In the present embodiment, the substrate 51 is bonded to the substrate 21 via the interlayer insulating films 55 and 26.

The contact plug 56, the contact hole 57, the via plug 58, and the wiring 59 are formed in the interlayer insulating film 55 on the substrate 51. The contact plug 56 is provided on the substrate 51. The contact hole 57 is provided on the contact plug 56 or the like. A part of the ferroelectric capacitor C is embedded in the contact hole 57 and is electrically connected to the contact plug 56 in the contact hole 57. The via plug 58 is provided on the ferroelectric capacitor C and is electrically connected to the ferroelectric capacitor C. The wiring 59 is provided on the via plug 58 and is in contact with the wiring 36.

The multilayer wiring structure 57′, the via plug 58′, and the wiring 59′ are formed in the interlayer insulating film 55 above the substrate 51. The multilayer wiring structure 57′ is provided at substantially the same height as the contact hole 57. The via plug 58′ is provided on the multilayer wiring structure 57′ and is located in the same plug layer as the via plug 58. The wiring 59′ is provided on the via plug 58′, is located in the same wiring layer as the wiring 59, and is in contact with the wiring 36′.

In the present embodiment, since the upper layer S1 of the solid-state imaging device and the lower layer S2 of the solid-state imaging device are manufactured by different processes, the ferroelectric capacitor C can be formed without being limited to the process generation of the upper layer S1. For example, by manufacturing the ferroelectric capacitor C by a finer technology, the capacitance of the ferroelectric capacitor C can be increased.

Note that the lower layer S2 may include a memory such as FeRAM, DRAM, or FRAM instead of the logic circuit or together with the logic circuit. For example, in a case where the lower layer S2 includes the FeRAM, the ferroelectric capacitor C and the FeRAM can be simultaneously formed by the same process. This makes it possible to reduce the number of steps for manufacturing the lower layer S2.

### Sixth Embodiment

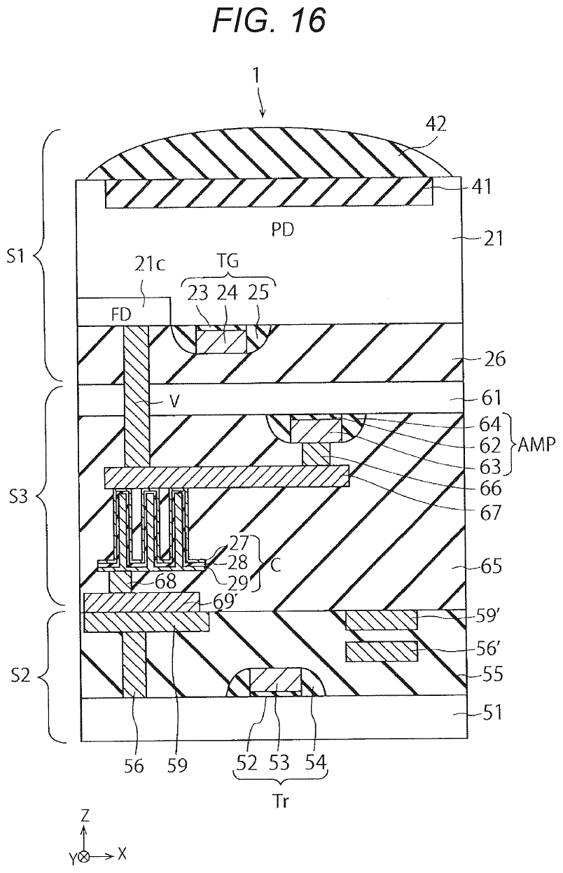

FIG. 16 is a cross-sectional view illustrating a structure of a solid-state imaging device of a sixth embodiment.

Similarly to the solid-state imaging devices of the fourth and fifth embodiments, the solid-state imaging device of the present embodiment is a back-illuminated type. However, the solid-state imaging device of the present embodiment has a three-layer structure including an upper layer S1, a lower layer S2, and an intermediate layer S3.

The upper layer S1 of the present embodiment has a structure similar to the upper layer S1 of the fifth embodiment. However, the upper layer S1 of the present embodiment does not include the amplification transistor AMP or the like.

The lower layer S2 of the present embodiment has a structure similar to the lower layer S2 of the fifth embodiment. However, the lower layer S2 of the present embodiment does not include the ferroelectric capacitor C or the like. Furthermore, the lower layer S2 of the present embodiment includes a wiring 56′ at substantially the same height as a contact plug 56.

The intermediate layer S3 includes a substrate 61, a gate insulating film 62, a gate electrode 63, and a sidewall insulating film 64 included in an amplification transistor AMP, an interlayer insulating film 65, a via plug 66, a wiring 67, a via plug 68, and a wiring 69. The intermediate layer S3 further includes an electrode 27, a ferroelectric film 28, and an electrode 29 included in a ferroelectric capacitor C. The substrate 61 is an example of the third substrate of the present disclosure. Furthermore, the interlayer insulating film 65 is an example of the third insulating film of the present disclosure.

The substrate 61 is, for example, a semiconductor substrate such as a silicon substrate. An upper surface of the substrate 61 is in contact with a lower surface of the interlayer insulating film 26. In the present embodiment, the substrate 61 is bonded to the substrate 21 via the interlayer insulating film 26.

The intermediate layer S3 includes a pixel transistor other than a transfer transistor TG under the substrate 61, and includes, for example, a reset transistor RST, an amplification transistor AMP, and a selection transistor SEL. FIG. 16 illustrates the amplification transistor AMP provided under the substrate 61. However, the amplification transistor AMP illustrated in FIG. 16 includes not the gate insulating film 23, the gate electrode 24, and the sidewall insulating film 25 formed on a lower surface of the substrate 21 but the gate insulating film 62, the gate electrode 63, and the sidewall insulating film 64 formed on a lower surface of the substrate 61. As described above, the solid-state imaging device according to the present embodiment includes a photodiode region R1 in the upper layer S1, a logic circuit region R3 in the lower layer S2, and a pixel transistor region R2 in the intermediate layer S3.

The interlayer insulating film 65 is formed under the substrate 61 so as to cover the amplification transistor AMP and the like. A lower surface of the interlayer insulating film 65 is in contact with an upper surface of the interlayer insulating film 55. In the present embodiment, the substrate 61 is bonded to the substrate 51 via the interlayer insulating films 65 and 55.

The via plug 66, the wiring 67, the via plug 68, and the wiring 69 are formed in the interlayer insulating film 65 under the substrate 61. The via plug 66 is provided under the gate electrode 63 of the amplification transistor AMP. The wiring 67 is provided under the via plug 66. A part of the ferroelectric capacitor C is embedded in a contact hole below the wiring 67, and is electrically connected to the wiring 67 in the contact hole. The via plug 68 is provided under the ferroelectric capacitor C and is electrically connected to the ferroelectric capacitor C. The wiring 69 is provided under the via plug 68 and is in contact with the wiring 59.

The solid-state imaging device of the present embodiment further includes a through plug V formed in the upper layer S1 and the intermediate layer S3. The through plug V is provided in the interlayer insulating film 26, the substrate 61, and the interlayer insulating film 65, and electrically connects a floating diffusion portion FD and the wiring 67. The through plug V of the present embodiment is electrically insulated from the substrate 61 by an insulating film (not illustrated).

In the present embodiment, since the upper layer S1, the lower layer S2, and the intermediate layer S3 of the solid-state imaging device are manufactured by different processes, it is possible to form the ferroelectric capacitor C without being limited to the process generation of the upper layer S1. For example, by manufacturing the ferroelectric capacitor C by a finer technology, the capacitance of the ferroelectric capacitor C can be increased. Furthermore, it is possible to reduce the influence of the thermal history generated in the process of forming the ferroelectric capacitor C.

### Seventh Embodiment

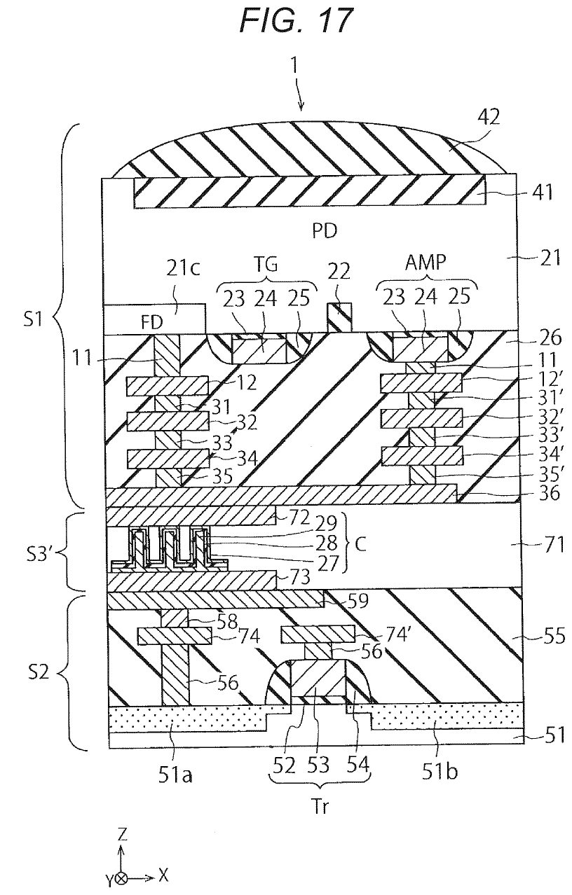

FIG. 17 is a cross-sectional view illustrating a structure of a solid-state imaging device of a seventh embodiment.

Similarly to the solid-state imaging devices of the fourth to sixth embodiments, the solid-state imaging device of the present embodiment is a back-illuminated type. However, the solid-state imaging device of the present embodiment has a three-layer structure including an upper layer S1, a lower layer S2, and an intermediate layer S3′.

The upper layer S1 of the present embodiment has a structure similar to the upper layer S1 of the fifth embodiment (FIG. 15). However, the upper layer S1 of the present embodiment includes a wiring 12′, a via plug 31′, a via plug 33′, and a via plug 35′ instead of the wiring 36′. The wiring 12′, the via plug 31′, a wiring 32′, the via plug 33′, a wiring 34′, and the via plug 35′ of the present embodiment are sequentially formed under a gate electrode 24 of an amplification transistor AMP via a contact plug 11. Furthermore, a wiring 36 of the present embodiment is formed under a via plug 35 and the via plug 35′.

The solid-state imaging device of the present embodiment includes the intermediate layer S3′ instead of the intermediate layer S3. The intermediate layer S3′ includes a substrate 71, a wiring 72, a wiring 73, and an electrode 27, a ferroelectric film 28, and an electrode 29 included in a ferroelectric capacitor C. Similarly to the substrate 61, the substrate 71 is an example of the third substrate of the present disclosure.

The substrate 71 is, for example, a semiconductor substrate such as a silicon substrate. An upper surface of the substrate 71 is in contact with a lower surface of an interlayer insulating film 26, and a lower surface of the substrate 71 is in contact with an upper surface of an interlayer insulating film 55. In the present embodiment, the substrate 71 is bonded to a substrate 21 via the interlayer insulating film 26, and the substrate 71 is bonded to a substrate 51 via the interlayer insulating film 55.

The wiring 72 is provided in the substrate 71 and is in contact with the wiring 36. A part of the ferroelectric capacitor C is embedded in a contact hole below the wiring 72, and is electrically connected to the wiring 72 in the contact hole. The wiring 73 is provided under the ferroelectric capacitor C, is electrically connected to the ferroelectric capacitor C, and is in contact with the wiring 73. As described above, the ferroelectric capacitor C of the present embodiment is provided in the substrate 71. The wiring 72, the ferroelectric capacitor C, and the wiring 73 of the present embodiment are electrically insulated from the substrate 71 by an insulating film (not illustrated).

The lower layer S2 of the present embodiment has a structure similar to the lower layer S2 of the sixth embodiment (FIG. 16). However, the lower layer S2 of the present embodiment includes a via plug 58, a wiring 74, and a wiring 74′. FIG. 17 further illustrates diffusion regions 51a and 51b (source and drain regions of a transistor Tr) in the substrate 51. In the present embodiment, a contact plug 56, the wiring 74, the via plug 58, and a wiring 59 are sequentially formed on the diffusion region 51a, and a contact plug 56 and the wiring 74′ are sequentially formed on a gate electrode 53 of the transistor Tr.

In the present embodiment, since the upper layer S1, the lower layer S2, and the intermediate layer S3′ of the solid-state imaging device are manufactured by different processes, it is possible to form the ferroelectric capacitor C without being limited to the process generation of the upper layer S1. For example, by manufacturing the ferroelectric capacitor C by a finer technology, the capacitance of the ferroelectric capacitor C can be increased. Furthermore, it is possible to reduce the influence of the thermal history generated in the process of forming the ferroelectric capacitor C.

### Eighth Embodiment

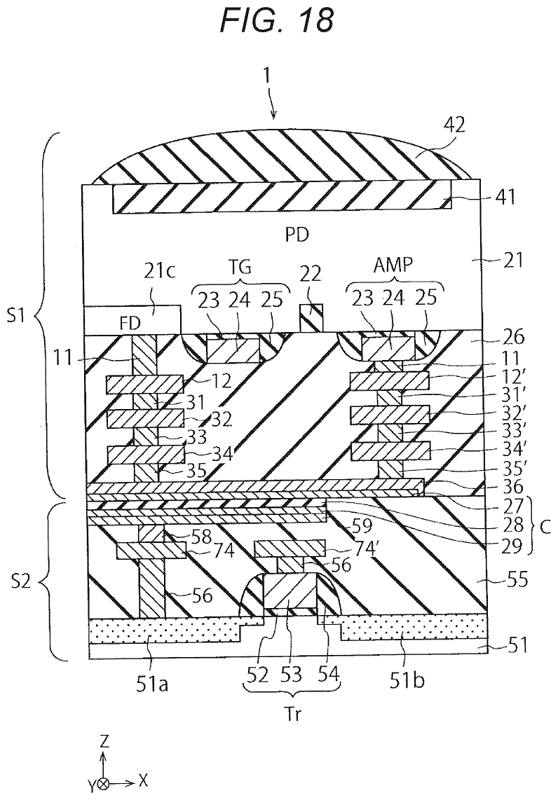

FIG. 18 is a cross-sectional view illustrating a structure of a solid-state imaging device of an eighth embodiment.

Similarly to the solid-state imaging devices of the fourth to seventh embodiments, the solid-state imaging device of the present embodiment is a back-illuminated type. However, the solid-state imaging device of the present embodiment has a two-layer structure including an upper layer S1 and a lower layer S2.

The upper layer S1 and the lower layer S2 of the present embodiment have structures similar to those of the upper layer S1 and the lower layer S2 of the seventh embodiment (FIG. 17), respectively. However, an upper surface of an interlayer insulating film 55 of the present embodiment is in contact with a lower surface of an interlayer insulating film 26, and a substrate 51 of the present embodiment is bonded to a substrate 21 via the interlayer insulating films 55 and 26. Furthermore, a ferroelectric capacitor C of the present embodiment is provided between the interlayer insulating film 26 and the interlayer insulating film 55. The interlayer insulating films 26 and 55 are examples of first and second insulating films of the present disclosure, respectively.

In the upper layer S1 of the present embodiment, an electrode 27 is formed under a wiring 36 in the interlayer insulating film 26. On the other hand, in the lower layer S2 of the present embodiment, an electrode 29 and a ferroelectric film 28 are sequentially formed on a wiring 59 in the interlayer insulating film 55. As a result, the ferroelectric capacitor C of the present embodiment is provided between the wiring 36 and the wiring 59, and is electrically connected to these wirings 36 and 59. Note that the ferroelectric film 28 of the present embodiment may be formed in the interlayer insulating film 26 instead of the interlayer insulating film 55.

In FIG. 18, the electrode 27 is a lowermost wiring in the upper layer S1, and the electrode 29 is an uppermost wiring in the lower layer S2. In FIG. 18, a lower surface of the wiring 36 is covered with the electrode 27, and an upper surface of the wiring 59 is covered with the electrode 29.

In the present embodiment, since the upper layer S1 and the lower layer S2 of the solid-state imaging device are manufactured by different processes, the ferroelectric capacitor C can be formed without being limited to the process generation of the upper layer S1. For example, by manufacturing the ferroelectric capacitor C by a finer technology, the capacitance of the ferroelectric capacitor C can be increased. Furthermore, by adopting the structure as illustrated in FIG. 18, it is possible to reduce the process cost for the electrodes 27 and 29.

### Ninth Embodiment

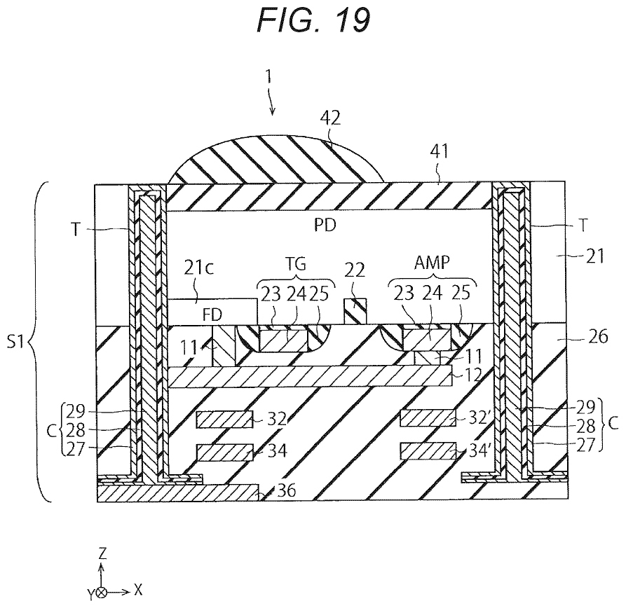

FIG. 19 is a cross-sectional view illustrating a structure of a solid-state imaging device of a ninth embodiment.

Similarly to the solid-state imaging devices of the fourth to eighth embodiments, the solid-state imaging device of the present embodiment is a back-illuminated type. As illustrated in FIG. 19, the solid-state imaging device of the present embodiment includes at least an upper layer 51.

The upper layer S1 of the present embodiment has a structure similar to the upper layer S1 of the fifth embodiment (FIG. 15). However, the upper layer S1 of the present embodiment includes an element isolation groove (pixel isolation groove) T formed in a substrate 21 and an interlayer insulating film 26, and a ferroelectric capacitor C embedded in the element isolation groove T. The element isolation groove T has, for example, a mesh shape in plan view.

The ferroelectric capacitor C of the present embodiment includes an electrode 27, a ferroelectric film 28, and an electrode 29 sequentially provided in the element isolation groove T. In the present embodiment, a side surface of the electrode 27 is in contact with a side surface of a wiring 12, and the electrode 27 is electrically connected to the wiring 12. Furthermore, a lower surface of the electrode 29 is in contact with an upper surface of a wiring 36, and the electrode 29 is electrically connected to the wiring 36. Note that, in the substrate 21 of the present embodiment, the electrode 29 is electrically insulated from the substrate 21 by an insulating film (not illustrated).

According to the present embodiment, the capacitance of the ferroelectric capacitor C can be increased by increasing a length of the ferroelectric capacitor C in the Z direction. In order to reduce crosstalk between the pixels 1, the electrodes 27 and 29 of the present embodiment desirably include a metal layer having a high light shielding property or a metal layer having a large film thickness.

### Tenth Embodiment

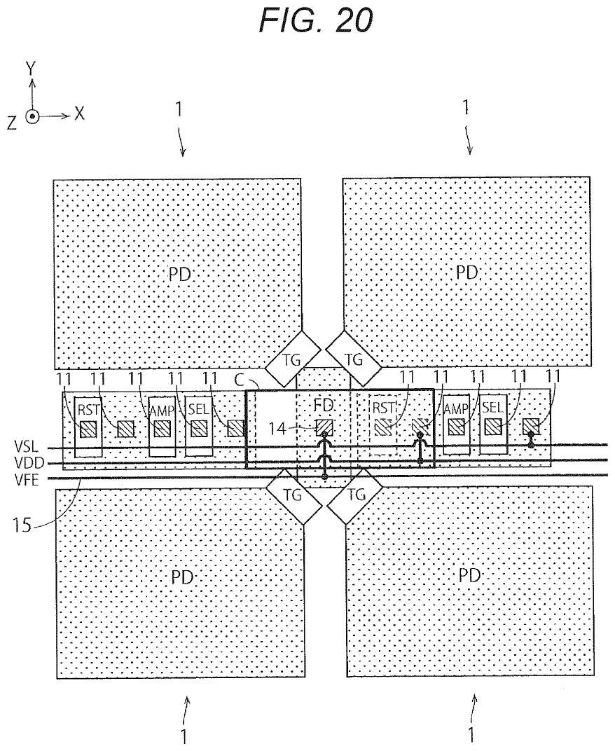

FIG. 20 is a plan view illustrating a structure of a solid-state imaging device according to a tenth embodiment.

Similarly to FIG. 3, FIG. 20 illustrates a planar structure of the solid-state imaging device of the present embodiment. A ferroelectric capacitor C of the present embodiment is shared by a plurality of pixels 1. FIG. 20 illustrates photodiodes PD and transfer transistors TG in the four pixels 1, and one ferroelectric capacitor C and one floating diffusion portion FD shared by these pixels 1. Moreover, in FIG. 20, the right two pixels 1 share one set of a reset transistor RST, an amplification transistor AMP, and a selection transistor SEL, and the left two pixels 1 share another set of a reset transistor RST, an amplification transistor AMP, and a selection transistor SEL.

FIG. 20 further illustrates a VSL wiring (vertical signal line 8), a VDD wiring, a VFE wiring, a plurality of contact plugs 11, a wiring 14, and a wiring 15, similarly to FIG. 3. The wiring 15 corresponds to the VFE wiring illustrated in FIG. 20.

According to the present embodiment, since the plurality of pixels 1 shares the ferroelectric capacitor C, the area efficiency of the solid-state imaging device can be improved.

### Eleventh Embodiment

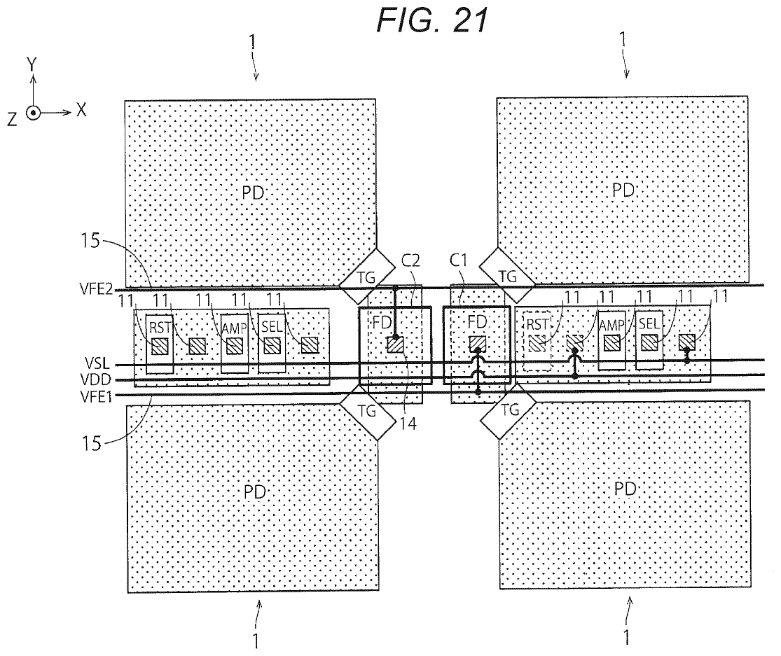

FIG. 21 is a plan view illustrating a structure of a solid-state imaging device according to an eleventh embodiment.

Similarly to FIGS. 3 and 20, FIG. 21 illustrates a planar structure of the solid-state imaging device of the present embodiment. Similarly to FIG. 20, FIG. 21 illustrates photodiodes PD and transfer transistors TG in four pixels 1. Also in FIG. 21, the right two pixels 1 share one set of a reset transistor RST, an amplification transistor AMP, and a selection transistor SEL, and the left two pixels 1 share another set of a reset transistor RST, an amplification transistor AMP, and a selection transistor SEL.

In FIG. 21, one ferroelectric capacitor C (Hereinafter, denoted by reference sign C1) and one floating diffusion portion FD are disposed between the right two pixels 1, and one ferroelectric capacitor C (Hereinafter, it is represented by reference sign C2) and one floating diffusion portion FD are also disposed between the left two pixels 1. These two sets of the ferroelectric capacitor C and the floating diffusion portion FD are shared by the four pixels 1. The ferroelectric capacitor C1 is an example of the first capacitor of the present disclosure, and the ferroelectric capacitor C2 is an example of the second capacitor of the present disclosure.

FIG. 21 further illustrates a VSL wiring (vertical signal line 8), a VDD wiring, a VFE1 wiring, a VFE2 wiring, a plurality of contact plugs 11, a wiring 14, and a plurality of wirings 15. These wirings 15 correspond to the VFE1 wiring and the VFE2 wiring illustrated in FIG. 21. The VFE1 wiring is an example of the first wiring of the present disclosure, and the VFE2 wiring is an example of the second wiring of the present disclosure.

Each of the ferroelectric capacitors C1 and C2 has the same structure and arrangement as those of the ferroelectric capacitor C illustrated in FIGS. 2 and 4. However, an electrode 29 of the ferroelectric capacitor C1 is electrically connected to the VFE1 wiring, and an electrode 29 of the ferroelectric capacitor C2 is electrically connected to the VFE2 wiring. The VFE1 wiring supplies a voltage VFE1 to the electrode 29 of the ferroelectric capacitor C1, and the VFE2 wiring supplies a voltage VFE2 to the electrode 29 of the ferroelectric capacitor C2. Details of the VFE1 voltage and the VFE2 voltage are similar to those of the VFE voltage described in the first embodiment.

According to the present embodiment, by controlling the voltages of the ferroelectric capacitors C1 and C2 by the VFE1 and VFE2 wirings, respectively, the states of the ferroelectric capacitors C1 and C2 can be independently controlled. In the solid-state imaging device according to the present embodiment, for example, before reading, the state of the ferroelectric capacitor C1 is set to the “Cfe low state” in advance, and the state of the ferroelectric capacitor C2 is set to the “Cfe high state” in advance. As a result, it is not necessary to sequentially perform two reading operations of reading in the “Cfe low state” and reading in the “Cfe high state” in each pixel 1, and it is possible to improve the simultaneity of imaging.

### Twelfth Embodiment

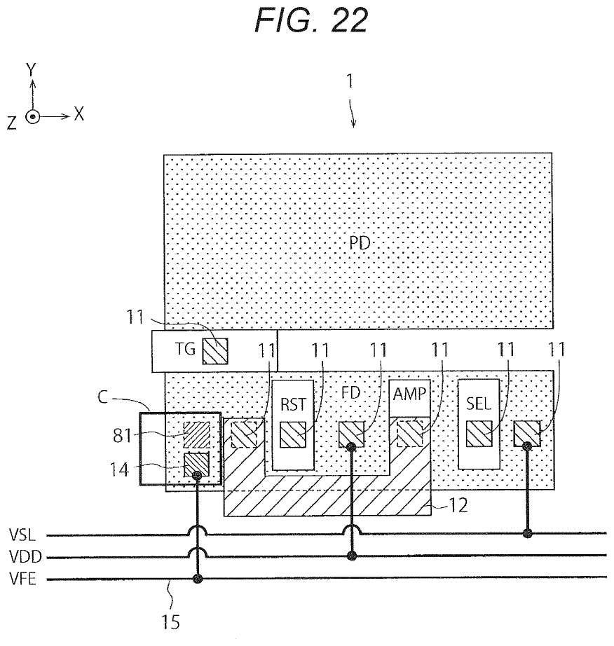

FIG. 22 is a plan view illustrating a structure of a solid-state imaging device according to a twelfth embodiment.

Similarly to FIGS. 3, 20, and 21, FIG. 22 illustrates a planar structure of the solid-state imaging device of the present embodiment. The solid-state imaging device (FIG. 22) of the present embodiment has a structure similar to the structure illustrated in FIG. 3, but includes a contact plug 81 not illustrated in FIG. 3.

FIGS. 3 and 4 illustrate the contact plug 11 provided on the floating diffusion portion FD below the ferroelectric capacitor C. The contact plug 11 not only electrically connects the floating diffusion portion FD and the amplification transistor AMP, but also electrically connects the floating diffusion portion FD and the ferroelectric capacitor C.

FIG. 22 also illustrates a contact plug 11 provided on a floating diffusion portion FD below a ferroelectric capacitor C. The contact plug 11 electrically connects the floating diffusion portion FD and an amplification transistor AMP, but does not electrically connect the floating diffusion portion FD and the ferroelectric capacitor C. In FIG. 22, the contact plug 81 electrically connects the floating diffusion portion FD and the ferroelectric capacitor C. The contact plug 11 is an example of the first contact plug of the present disclosure, and the contact plug 81 is an example of the second contact plug of the present disclosure.

According to the present embodiment, since the amplification transistor AMP and the ferroelectric capacitor C are electrically connected to the floating diffusion portion FD by the contact plugs 11 and 81, respectively, it is possible to reduce variations in parasitic capacitance for each pixel 1. Note that a switch transistor TSW may be disposed between the floating diffusion portion FD and the ferroelectric capacitor C of the present embodiment.

### Thirteenth Embodiment

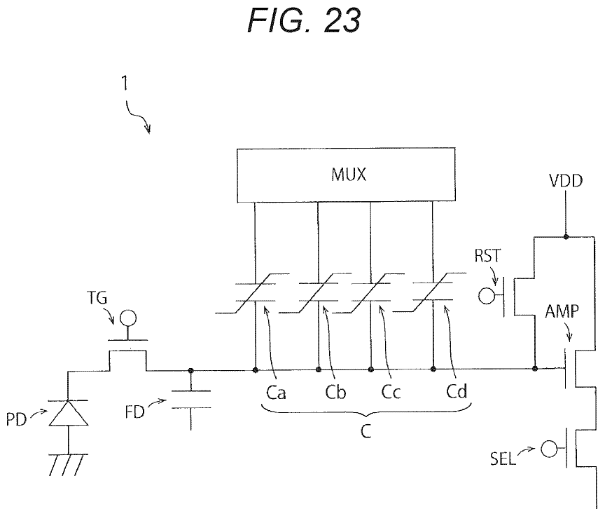

FIG. 23 is a circuit diagram illustrating a configuration of a solid-state imaging device according to a thirteenth embodiment.

Similarly to FIGS. 2 and 11, FIG. 23 illustrates a circuit configuration of one pixel 1 in the solid-state imaging device of the present embodiment. A ferroelectric capacitor C of the present embodiment includes a plurality of ferroelectric capacitors Ca to Cd connected in parallel. One electrode of each of the ferroelectric capacitors Ca to Cd is electrically connected to a transfer transistor TG, a floating diffusion portion FD, a reset transistor RST, and an amplification transistor AMP. The other electrode of each of the ferroelectric capacitors Ca to Cd is electrically connected to a multiplexer MUX. The solid-state imaging device of the present embodiment can independently control these ferroelectric capacitors Ca to Cd. The ferroelectric capacitors Ca to Cd are examples of the partial capacitors of the present disclosure, and the multiplexer MUX is an example of the selection unit of the present disclosure.

The ferroelectric capacitors Ca to Cd of the present embodiment have different capacitances. For example, the capacitances of the ferroelectric capacitors Ca, Cb, Cc, and Cd are set to 1:2:4:8. The multiplexer MUX selects one or more ferroelectric capacitors from the ferroelectric capacitors Ca to Cd. For example, in a case where the capacitance of each of the ferroelectric capacitors Ca to Cd can take two types of values, the conversion efficiency ΔV can be switched to 2⁴ (=16) values by the multiplexer MUX selecting one or more ferroelectric capacitors. By such switching, the dynamic range of the solid-state imaging device can be further improved. The capacitance of the ferroelectric capacitor C of the present embodiment is a sum (combined capacitance) of the capacitances of the selected ferroelectric capacitors.

Note that a switch transistor TSW may be disposed between the floating diffusion portion FD and the ferroelectric capacitor C of the present embodiment. Furthermore, the number of the ferroelectric capacitors Ca to Cd included in the ferroelectric capacitor C of the present embodiment may be other than four.

### Fourteenth Embodiment

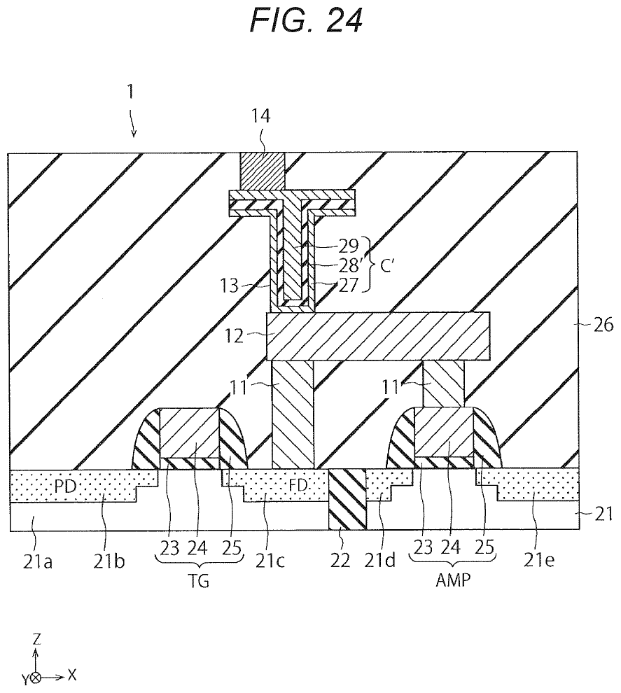

FIG. 24 is a cross-sectional view illustrating a structure of a solid-state imaging device according to a fourteenth embodiment.

Similarly to FIG. 4, FIG. 24 illustrates a structure of one pixel 1 in the solid-state imaging device of the present embodiment. The solid-state imaging device (FIG. 24) of the present embodiment has a structure similar to the structure illustrated in FIG. 4, but includes an antiferroelectric capacitor C′ instead of the ferroelectric capacitor C.

The antiferroelectric capacitor C′ includes an electrode 27, an antiferroelectric film 28′, and an electrode 29 which are sequentially formed inside and outside a contact hole 13. Inside the contact hole 13, the electrode 27, the antiferroelectric film 28′, and the electrode 29 are sequentially formed on an upper surface of a wiring 12 and a side surface of an interlayer insulating film 26. Outside the contact hole 13, the electrode 27, the antiferroelectric film 28′, and the electrode 29 are sequentially formed on an upper surface of the interlayer insulating film 26. The electrode 27 is in contact with the upper surface of the wiring 12 and is electrically connected to the wiring 12. The electrode 29 is in contact with a lower surface of the wiring 14 and is electrically connected to the wiring 14. As described above, the antiferroelectric capacitor C′ of the present embodiment has a three-dimensional structure having expansion in the X direction, the Y direction, and the Z direction. Note that the antiferroelectric capacitor C′ may have a structure similar to that of the ferroelectric capacitor C illustrated in other than FIG. 4 in the first to thirteenth embodiments.

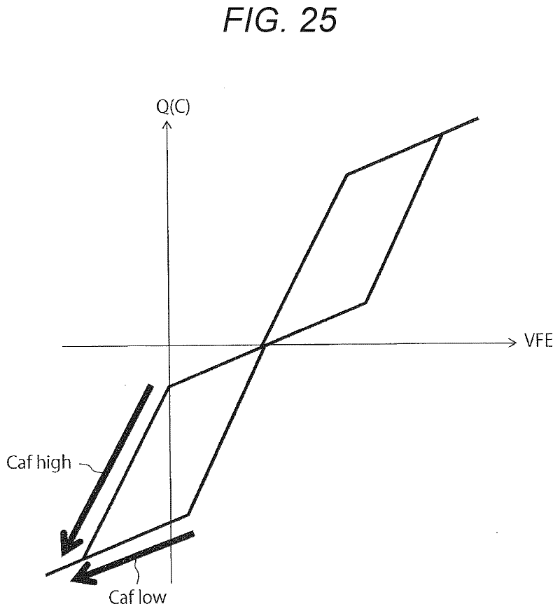

FIG. 25 is a graph for explaining an operation of the solid-state imaging device of the fourteenth embodiment.

Similarly to A of FIG. 9, FIG. 25 illustrates a Q-V curve for explaining an operation of the antiferroelectric capacitor C′ of the present embodiment. The Q-V curve of the antiferroelectric capacitor C′ draws hysteresis as illustrated in FIG. 25. Furthermore, the capacitance Caf of the antiferroelectric capacitor C′ represented by the slope of the Q-V curve can take two types of values Caf low and Caf high as illustrated in FIG. 25. The Q-V curve illustrated in FIG. 25 has a shape close to two parallelograms. Caf low corresponds to the inclination of a lower side of the left parallelogram, and Caf high corresponds to the inclination of a left side of the left parallelogram. According to the present embodiment, by using the hysteresis of the antiferroelectric capacitor C′, the conversion efficiency ΔV can be switched to two types of values similarly to the case of using the hysteresis of the ferroelectric capacitor C. Note that, similarly to the case of the ferroelectric capacitors C of the first to thirteenth embodiments, the antiferroelectric capacitor C′ of the present embodiment may be applied to the case of switching the conversion efficiency ΔV to three types of values.

Note that, in a case where the antiferroelectric capacitor C′ is used as in the present embodiment, it is desirable to shift an intersection of the two parallelograms in the Q-V curve to the right side from the origin of the Q-V coordinate as illustrated in FIG. 25. As a result, the contents described for the ferroelectric capacitors C of the first to thirteenth embodiments can be directly applied to the antiferroelectric capacitor C′ of the present embodiment. Such a shift can be realized, for example, by forming the electrode 27 and the electrode 29 with different materials having different work functions.

For example, in a case where an HfO₂-based material is used, the antiferroelectric film 28′ can be realized by a crystal containing a large amount of tetragonal phase. The tetragonal phase is more stable than the orthoboric phase, which is a metastable state from which the ferroelectrics originate, and thus can provide a stable capacitance change.

### Fifteenth Embodiment

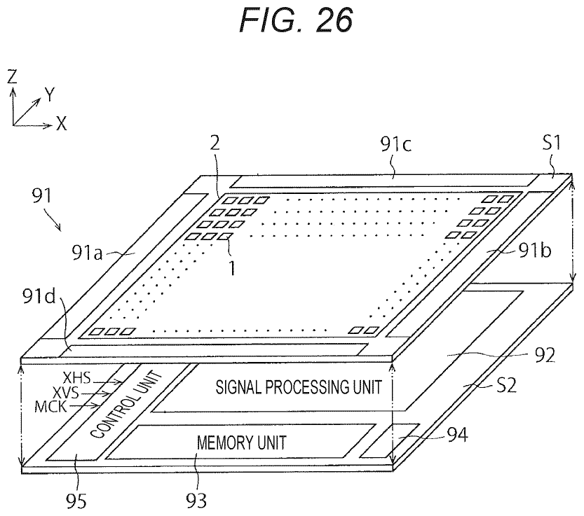

FIG. 26 is a perspective view illustrating a structure of a solid-state imaging device according to a fifteenth embodiment.

The solid-state imaging device of the present embodiment has a two-layer structure including an upper layer S1 and a lower layer S2. The upper layer S1 includes a pixel array region 2 including a plurality of pixels 1 and a plurality of connection portions 91. Each of these connecting portions 91 include a pad portion 91a, a pad portion 91b, a via portion 91c, and a via portion 91d. The lower layer S2 includes a signal processing unit 92, a memory unit 93, a data processing unit 94, and a control unit 95. The configuration of the solid-state imaging device illustrated in FIG. 1 can be realized by, for example, the structure illustrated in FIG. 26.

The pad portion 91a, the pad portion 91b, the via portion 91c, and the via portion 91d are disposed around the pixel array region 2. The pad portions 91a and 91b are provided to electrically connect the solid-state imaging device of the present embodiment to another device. The via portions 91c and 91d are provided to electrically connect the upper layer S1 of the present embodiment to the lower layer S2.

The signal processing unit 92 performs various processes on a signal from the pixel array region 2. The memory unit 93 stores image data processed by the signal processing unit 92. The data processing unit 94 performs various processing on the image data stored in the memory unit 93, and outputs the processed image data to another device. The control unit 95 controls various operations of the solid-state imaging device of the present embodiment, and functions as, for example, the control circuit 3 illustrated in FIG. 1.

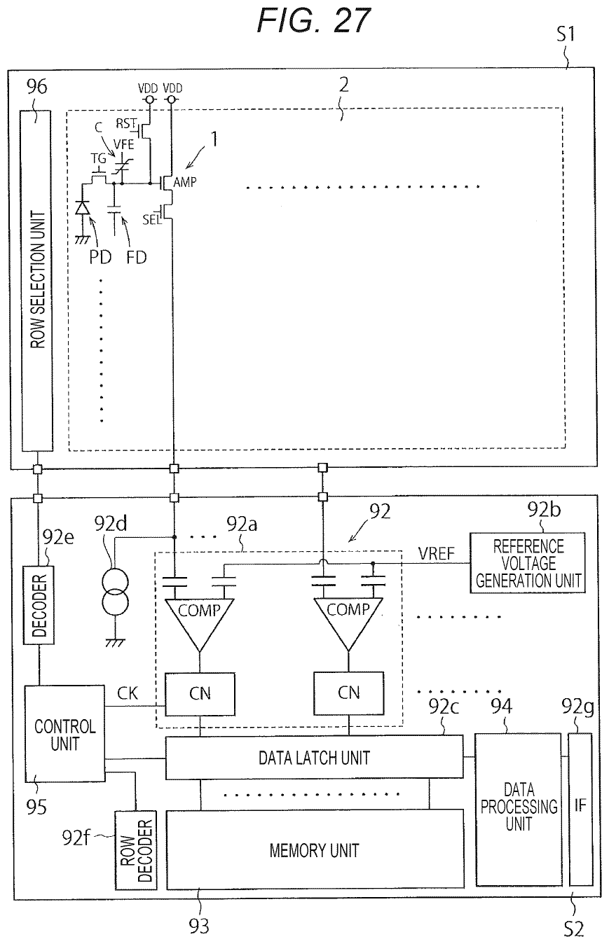

FIG. 27 is a block diagram illustrating a configuration of the solid-state imaging device according to the fifteenth embodiment.

FIG. 27 illustrates the pixel array region 2 and a row selection unit 96 in the upper layer S1, and the signal processing unit 92, the memory unit 93, the data processing unit 94, and the control unit 95 in the lower layer S2. Each of the pixels 1 in the pixel array region 2 in FIG. 27 has the configuration illustrated in FIG. 2. Furthermore, the signal processing unit 92 includes an analog to digital (A/D) converter 92a, a reference voltage generation unit 92b, a data latch unit 92c, a current source 92d, a decoder 92e, a row decoder 92f, and an interface (I/F) unit 92g.

The A/D converter 92a includes two comparators CMP and two counters CN, and converts a signal from the pixel array region 2 from an analog signal to a digital signal. The reference voltage generation unit 92b generates a reference signal VREF for the A/D converter 92a. The data latch unit 92c latches the digital signal from the A/D converter 92a. The current source 92d supplies a constant current to the A/D converter 92a. Under the control of the control unit 95, the decoder 92e and the row decoder 92f specify a row address and provide an address signal for specifying a selected row to the row selection unit 96. The I/F unit 92g functions as an interface for outputting the processed image data to another device.

Note that the configuration of the solid-state imaging device illustrated in FIG. 1 may be implemented by the structure illustrated in FIG. 26 or may be implemented by another structure.

### Application Example

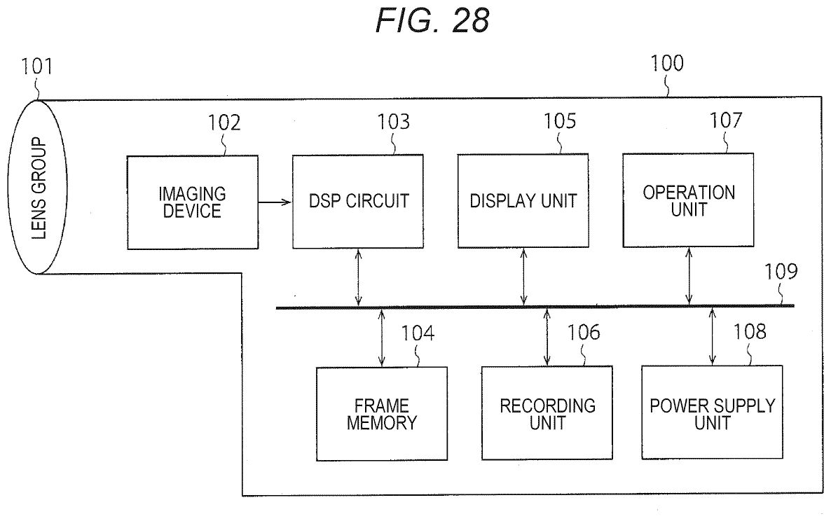

FIG. 28 is a block diagram illustrating a configuration example of an electronic device. The electronic device illustrated in FIG. 28 is a camera 100.

The camera 100 includes an optical unit 101 including a lens group and the like, an imaging device 102 which is the solid-state imaging device according to any one of the first to fifteenth embodiments, a digital signal processor (DSP) circuit 103 which is a camera signal processing circuit, a frame memory 104, a display unit 105, a recording unit 106, an operation unit 107, and a power supply unit 108. Furthermore, the DSP circuit 103, the frame memory 104, the display unit 105, the recording unit 106, the operation unit 107, and the power supply unit 108 are connected to each other via a bus line 109.

The optical unit 101 captures incident light (image light) from a subject and forms an image on an imaging surface of the imaging device 102. The imaging device 102 converts an amount of incident light formed into an image on the imaging surface by the optical unit 101 into an electric signal on a pixel-by-pixel basis and outputs the electric signal as a pixel signal.

The DSP circuit 103 performs signal processing on the pixel signal output from the imaging device 102. The frame memory 104 is a memory for storing one screen of a moving image or a still image captured by the imaging device 102.

The display unit 105 includes, for example, a panel type display device such as a liquid crystal panel or an organic EL panel, and displays a moving image or a still image captured by the imaging device 102. The recording unit 106 records a moving image or a still image captured by the imaging device 102 on a recording medium such as a hard disk or a semiconductor memory.

The operation unit 107 issues operation commands for various functions of the camera 100 in response to an operation performed by a user. The power supply unit 108 appropriately supplies various power supplies, which are operation power supplies for the DSP circuit 103, the frame memory 104, the display unit 105, the recording unit 106, and the operation unit 107, to these power supply targets.

By using the solid-state imaging device according to any one of the first to fifteenth embodiments as the imaging device 102, acquisition of a good image can be expected.

The solid-state imaging device can be applied to various other products. For example, the solid-state imaging device may be mounted on any type of mobile bodies such as vehicles, electric vehicles, hybrid electric vehicles, motorcycles, bicycles, personal mobility, airplanes, drones, ships, and robots.

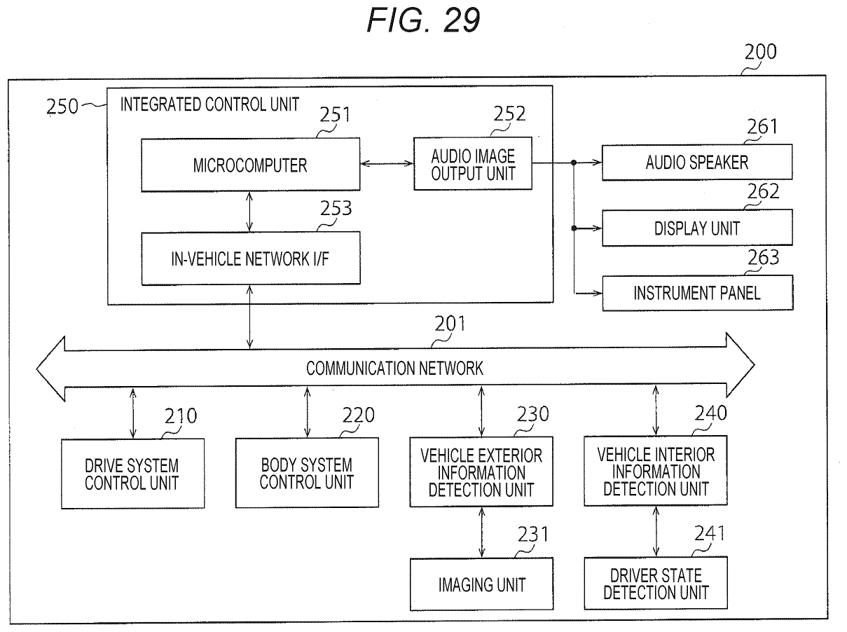

FIG. 29 is a block diagram illustrating a configuration example of a mobile body control system. The mobile body control system illustrated in FIG. 29 is a vehicle control system 200.

The vehicle control system 200 includes a plurality of electronic control units connected to each other via a communication network 201. In the example illustrated in FIG. 29, the vehicle control system 200 includes a drive system control unit 210, a body system control unit 220, an outside-vehicle information detection unit 230, an in-vehicle information detection unit 240, and an integrated control unit 250. FIG. 29 further illustrates a microcomputer 251, a sound/image output unit 252, and an in-vehicle network interface (I/F) 253 as components of the integrated control unit 250.

The drive system control unit 210 controls the operation of devices related to a driving system of a vehicle in accordance with various types of programs. For example, the drive system control unit 210 functions as a control device for a driving force generating device for generating a driving force of a vehicle, such as an internal combustion engine, a driving motor, or the like, a driving force transmitting mechanism for transmitting the driving force to wheels, a steering mechanism for adjusting a steering angle of the vehicle, a braking device for generating a braking force of the vehicle, and the like.

The body system control unit 220 controls the operation of various types of devices provided to a vehicle body in accordance with various types of programs. For example, the body system control unit 220 functions as a control device for a smart key system, a keyless entry system, a power window device, or various types of lamps (for example, a head lamp, a backup lamp, a brake lamp, a turn signal, a fog lamp, or the like). In this case, radio waves transmitted from a mobile device as an alternative to a key or signals of various types of switches can be input to the body system control unit 220. The body system control unit 220 receives inputs of such radio waves or signals, and controls a door lock device, the power window device, the lamps, or the like of the vehicle.

The outside-vehicle information detection unit 230 detects information on the outside of the vehicle including the vehicle control system 200. The outside-vehicle information detection unit 230 is connected with, for example, an imaging unit 231. The outside-vehicle information detection unit 230 makes the imaging unit 231 capture an image of the outside of the vehicle, and receives the captured image from the imaging unit 231. On the basis of the received image, the outside-vehicle information detection unit 230 may perform processing of detecting an object such as a human, an automobile, an obstacle, a sign, a character on a road surface, or the like, or processing of detecting a distance thereto.

The imaging unit 231 is an optical sensor that receives light and that outputs an electric signal corresponding to the amount of received light. The imaging unit 231 can output the electric signal as an image, or can output the electric signal as information on a measured distance. The light received by the imaging unit 231 may be visible light, or may be invisible light such as infrared light. The imaging unit 231 includes the solid-state imaging device according to any one of the first to fifteenth embodiments.

The in-vehicle information detection unit 240 detects information on the inside of the vehicle equipped with the vehicle control system 200. The in-vehicle information detection unit 240 is, for example, connected with a driver state detection unit 241 that detects a state of a driver. For example, the driver state detection unit 241 includes a camera that captures an image of the driver, and on the basis of detection information input from the driver state detection unit 241, the in-vehicle information detection unit 240 may calculate a degree of fatigue of the driver or a degree of concentration of the driver, or may determine whether or not the driver is dozing off. The camera may include the solid-state imaging device according to any one of the first to fifteenth embodiments, and may be, for example, the camera 100 illustrated in FIG. 28.

The microcomputer 251 can calculate a control target value for the driving force generating device, the steering mechanism, or the braking device on the basis of the information on the inside or outside of the vehicle obtained by the outside-vehicle information detection unit 230 or the in-vehicle information detection unit 240, and output a control command to the drive system control unit 210. For example, the microcomputer 251 can perform cooperative control intended to implement functions of an advanced driver assistance system (ADAS), the functions including collision avoidance or shock mitigation for the vehicle, following traveling based on a following distance, vehicle speed maintaining traveling, a warning of collision of the vehicle, a warning of deviation of the vehicle from a lane, and the like.

Furthermore, the microcomputer 251 can perform cooperative control intended for automated driving, which makes the vehicle travel autonomously without depending on the operation of the driver, or the like, by controlling the driving force generating device, the steering mechanism, the braking device, or the like on the basis of the information on the outside or inside of the vehicle obtained by the outside-vehicle information detection unit 230 or the in-vehicle information detection unit 240.

Furthermore, the microcomputer 251 can output a control command to the body system control unit 220 on the basis of the information on the outside of the vehicle obtained by the outside-vehicle information detection unit 230. For example, the microcomputer 251 can perform cooperative control for the purpose of preventing glare, such as switching from a high beam to a low beam, by controlling the headlamp according to the position of a preceding vehicle or an oncoming vehicle detected by the outside-vehicle information detection unit 230.

The sound/image output unit 252 transmits an output signal of at least one of a sound or an image to an output device that can visually or auditorily provide information to an occupant of the vehicle or the outside of the vehicle. In the example of FIG. 29, an audio speaker 261, a display unit 262, and an instrument panel 263 are illustrated as such output devices. The display unit 262 may, for example, include an on-board display or a head-up display.

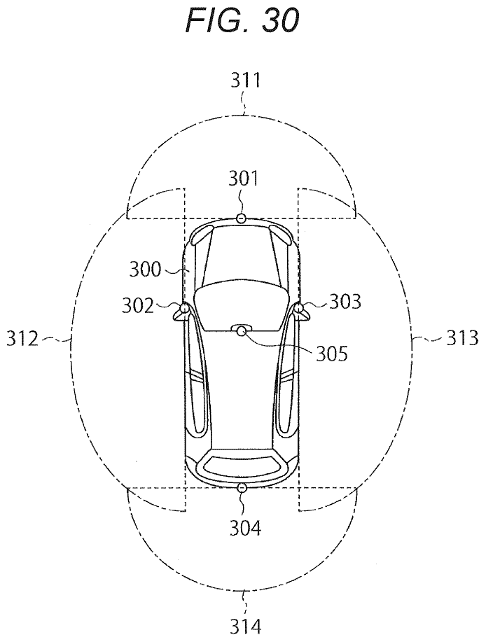

FIG. 30 is a plan view illustrating a specific example of a setting position of the imaging unit 231 in FIG. 29.

A vehicle 300 illustrated in FIG. 30 includes imaging units 301, 302, 303, 304, and 305 as the imaging unit 231. The imaging units 301, 302, 303, 304, and 305 are, for example, provided at positions on a front nose, side mirrors, a rear bumper, and a back door of the vehicle 300, and on an upper portion of a windshield in the interior of the vehicle.

The imaging unit 301 provided on the front nose mainly acquires an image of the front of the vehicle 300. The imaging unit 302 provided on the left side mirror and the imaging unit 303 provided on the right side mirror mainly acquire images of the sides of the vehicle 300. The imaging unit 304 provided to the rear bumper or the back door mainly acquires an image of the rear of the vehicle 300. The imaging unit 305 provided to the upper portion of the windshield in the interior of the vehicle mainly acquires an image of the front of the vehicle 300. The imaging unit 305 is used to detect, for example, a preceding vehicle, a pedestrian, an obstacle, a signal, a traffic sign, a lane, and the like.

FIG. 30 illustrates an example of imaging ranges of the imaging units 301, 302, 303, and 304 (hereinafter referred to as “imaging units 301 to 304”). An imaging range 311 represents the imaging range of the imaging unit 301 provided to the front nose. An imaging range 312 represents the imaging range of the imaging unit 302 provided to the left side mirror. An imaging range 313 represents the imaging range of the imaging unit 303 provided to the right side mirror. An imaging range 314 represents the imaging range of the imaging unit 304 provided to the rear bumper or the back door. For example, an overhead view of the vehicle 300 as viewed from above is obtained by superimposing image data captured by the imaging units 301 to 304. Hereinafter, the imaging ranges 311, 312, 313, and 314 are referred to as the “imaging ranges 311 to 314”.

At least one of the imaging units 301 to 304 may have a function of acquiring distance information. For example, at least one of the imaging units 301 to 304 may be a stereo camera including a plurality of imaging devices or an imaging device including pixels for phase difference detection.

For example, the microcomputer 251 (FIG. 29) calculates a distance to each three-dimensional object in the imaging ranges 311 to 314 and a temporal change of the distance (relative speed with respect to the vehicle 300) on the basis of the distance information obtained from the imaging units 301 to 304. On the basis of the calculation results, the microcomputer 251 can extract, as a preceding vehicle, a nearest three-dimensional object that is present on a traveling path of the vehicle 300 and travels in substantially the same direction as the vehicle 300 at a predetermined speed (for example, equal to or more than 0 km/h). Moreover, the microcomputer 251 can set a following distance to be maintained in front of a preceding vehicle in advance, and perform automatic brake control (including following stop control), automatic acceleration control (including following start control), or the like. According to this example, the cooperative control intended for automated driving that makes the vehicle travel autonomously and the like can be performed without depending on the operation of the driver.

For example, the microcomputer 251 can classify three-dimensional object data related to three-dimensional objects into a two-wheeled vehicle, a standard-sized vehicle, a large-sized vehicle, a pedestrian, a utility pole, and other three-dimensional objects on the basis of the distance information obtained from the imaging units 301 to 304, extract the classified three-dimensional object data, and use the extracted three-dimensional object data for automatic avoidance of an obstacle. For example, the microcomputer 251 identifies obstacles around the vehicle 300 as obstacles that the driver of the vehicle 300 can recognize visually and obstacles that are difficult for the driver of the vehicle 300 to recognize visually. Then, the microcomputer 251 determines a collision risk indicating a risk of collision with each obstacle, and in a situation in which the collision risk is equal to or higher than a set value and there is thus a possibility of collision, the microcomputer 251 outputs a warning to the driver via the audio speaker 261 or the display unit 262, and performs forced deceleration or avoidance steering via the drive system control unit 210 to assist in driving to avoid collision.

At least one of the imaging units 301 to 304 may be an infrared camera that detects infrared light. The microcomputer 251 can, for example, recognize a pedestrian by determining whether or not there is a pedestrian in images captured by the imaging units 301 to 304. Such recognition of a pedestrian is, for example, performed by a procedure of extracting characteristic points in the images captured by the imaging units 301 to 304 as infrared cameras and a procedure of determining whether or not an object is a pedestrian by performing pattern matching processing on a series of characteristic points representing the contour of the object. In a case where the microcomputer 251 determines that there is a pedestrian in the captured images captured by the imaging units 301 to 304 and recognizes the pedestrian, the sound/image output unit 252 controls the display unit 262 so that a square contour line for emphasis is displayed in a superimposed manner on the recognized pedestrian. Furthermore, the sound/image output unit 252 may also control the display unit 262 so that an icon or the like representing the pedestrian is displayed at a desired position.

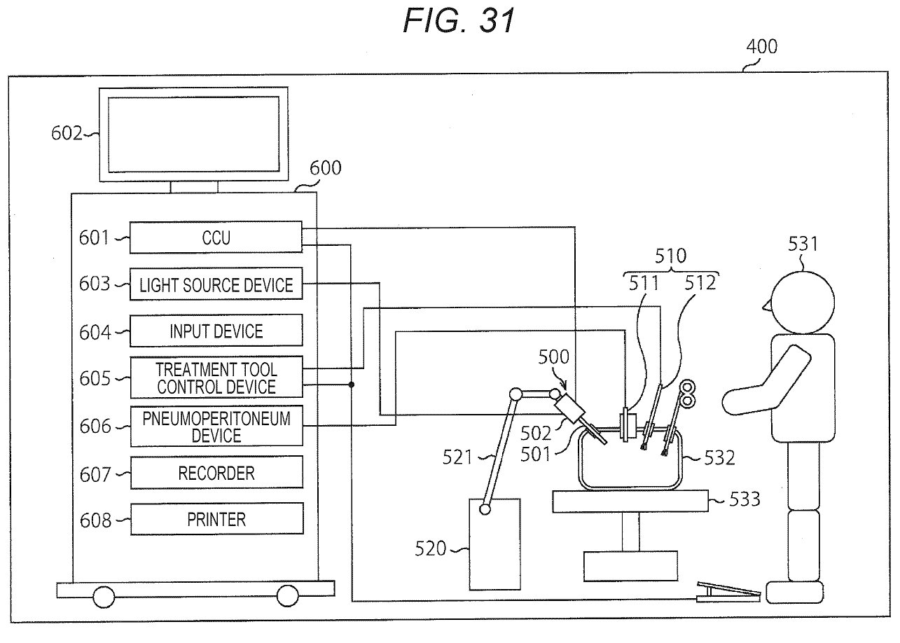

FIG. 31 is a diagram illustrating an example of a schematic configuration of an endoscopic surgery system to which the technology according to the present disclosure (the present technology) can be applied.

FIG. 31 illustrates a state in which an operator (doctor) 531 is performing surgery on a patient 532 on a patient bed 533 using an endoscopic surgery system 400. As illustrated, the endoscopic surgery system 400 includes an endoscope 500, other surgical tools 510 such as a pneumoperitoneum tube 511 and an energy treatment tool 512, a supporting arm device 520 for supporting the endoscope 500, and a cart 600 on which various devices for endoscopic surgery are mounted.

The endoscope 500 includes a lens barrel 501 having a region of a predetermined length from a distal end thereof to be inserted into a body cavity of the patient 532, and a camera head 502 connected to a proximal end of the lens barrel 501. Although the illustrated example illustrates the endoscope 500 is configured as a so-called rigid endoscope having a rigid lens barrel 501, the endoscope 500 may be a so-called flexible endoscope having a flexible lens barrel.

An opening in which an objective lens is fitted is provided at the distal end of the lens barrel 501. A light source device 603 is connected to the endoscope 500, and light generated by the light source device 603 is guided to the distal end of the lens barrel by a light guide extending in the lens barrel 501 and is emitted to an observation target in the body cavity of the patient 532 through the objective lens. Note that the endoscope 500 may be a forward-viewing endoscope, an oblique-viewing endoscope, or a side-viewing endoscope.

An optical system and an imaging element are provided in the camera head 502, and light reflected by the observation target (observation light) is collected on the imaging element by the optical system. The imaging element photoelectrically converts the observation light and generates an electric signal corresponding to the observation light, that is, an image signal corresponding to an observation image. The image signal is transmitted to a camera control unit (CCU) 601 as RAW data.

The CCU 601 includes a central processing unit (CPU), a graphics processing unit (GPU), and the like, and integrally controls the operations of the endoscope 500 and a display device 602. Moreover, the CCU 601 receives the image signal from the camera head 502 and applies, on the image signal, various types of image processing, for example, development processing (demosaicing processing) or the like for displaying an image based on the image signal.

The display device 602 displays the image based on the image signal which has been subjected to the image processing by the CCU 601 under the control of the CCU 601.

The light source device 603 includes, for example, a light source such as a light emitting diode (LED), and supplies irradiation light for imaging a surgical site or the like to the endoscope 500.

An input device 604 is an input interface for the endoscopic surgery system 11000. A user may input various types of information and instructions to the endoscopic surgery system 400 via the input device 604. For example, the user inputs an instruction and the like to change an imaging condition (type of irradiation light, magnification, focal length and the like) by the endoscope 500.

A treatment tool control device 605 controls driving of the energy treatment tool 512 for tissue cauterization, incision, blood vessel sealing, and the like. A pneumoperitoneum device 606 sends gas into the body cavity of the patient 532 via the pneumoperitoneum tube 511 in order to inflate the body cavity for a purpose of securing a field of view by the endoscope 500 and securing work space for the operator. A recorder 607 is a device that can record various types of information regarding surgery. A printer 608 is a device that can print various types of information regarding surgery in various formats such as a text, an image, or a graph.

Note that, the light source device 603 which supplies the irradiation light for imaging the surgical site to the endoscope 500 may include, for example, an LED, a laser light source, or a white light source obtained by combining these. In a case where the white light source includes a combination of RGB laser light sources, because an output intensity and an output timing of each color (each wavelength) can be controlled with high accuracy, the light source device 603 can adjust white balance of a captured image. Furthermore, in this case, by irradiating the observation target with the laser light from each of the R, G, and B laser light sources in time division and controlling driving of the imaging element of the camera head 502 in synchronism with the irradiation timing, images corresponding to R, G, and B can be captured in time division. According to this method, a color image can be obtained even if color filters are not provided for the image pickup element.

Furthermore, the driving of the light source device 603 may be controlled such that the intensity of light to be output is changed every predetermined time. The driving of the imaging element of the camera head 502 is controlled in synchronization with a timing of changing the light intensity to obtain the images in time division, and the obtained images are synthesized to enable generation of an image with a high dynamic range that does not have so-called black defect and halation.

Furthermore, the light source device 603 may be able to supply light in a predetermined wavelength band adapted to special light observation. In the special light observation, for example, by emitting light in a narrower band than irradiation light (in other words, white light) at the time of normal observation using wavelength dependency of a body tissue to absorb light, so-called narrow band imaging is performed in which an image of a predetermined tissue, such as a blood vessel in a mucosal surface layer, is captured with high contrast. Alternatively, in special light observation, fluorescent observation for obtaining an image from fluorescent light generated by irradiation of excitation light may be performed. In the fluorescence observation, a body tissue can be irradiated with excitation light to observe fluorescence from the body tissue (autofluorescence observation) or a reagent such as indocyanine green (ICG) is locally injected to a body tissue and irradiate the body tissue with excitation light corresponding to a fluorescent wavelength of the reagent to obtain a fluorescent image. The light source device 603 can be configured to supply narrow band light and/or excitation light adapted to such special light observation.

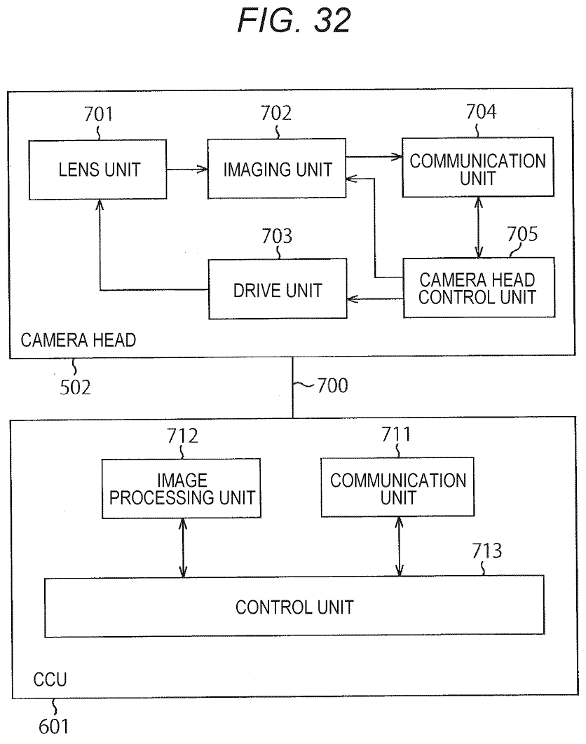

FIG. 32 is a block diagram illustrating an example of functional configurations of the camera head 502 and the CCU 601 illustrated in FIG. 31.

The camera head 502 includes a lens unit 701, an imaging unit 702, a drive unit 703, a communication unit 704, and a camera head control unit 705. The CCU 601 includes a communication unit 711, an image processing unit 712, and a control unit 713. The camera head 502 and the CCU 601 are connected to each other communicably by a transmission cable 700.

The lens unit 701 is an optical system provided at a connection portion with the lens barrel 501. The observation light captured from the distal end of the lens barrel 501 is guided to the camera head 502 and enters the lens unit 701. The lens unit 701 is configured by combining a plurality of lenses including a zoom lens and a focus lens.

The imaging unit 702 includes an imaging element. The number of imaging elements included in the imaging unit 702 may be one (so-called single plate type) or two or more (so-called multiple plate type). In a case where the imaging unit 702 is configured as the multiple plate type, for example, image signals corresponding to R, G, and B may be generated by the respective imaging elements, and a color image may be obtained by combining the generated image signals. Alternatively, the imaging unit 702 may include a pair of imaging elements for obtaining right-eye and left-eye image signals corresponding to three-dimensional (3D) display. By performing the 3D display, the surgeon 531 can grasp a depth of a living body tissue in a surgical site more accurately. Note that, in a case where the imaging unit 702 is configured as the multiple plate type, a plurality of systems of lens units 701 may be provided so as to correspond to the respective imaging elements. The imaging unit 702 is, for example, the solid-state imaging device according to any one of the first to fifteenth embodiments.

Furthermore, the imaging unit 702 is not necessarily provided in the camera head 502. For example, the imaging unit 702 may be provided inside the lens barrel 501 immediately behind the objective lens.

The drive unit 703 includes an actuator and moves the zoom lens and the focusing lens of the lens unit 701 by a predetermined distance along an optical axis under the control of the camera head control unit 705. With this arrangement, the magnification and focal point of the image captured by the imaging unit 702 may be appropriately adjusted.

The communication unit 704 includes a communication device for transmitting and receiving various types of information to and from the CCU 601. The communication unit 704 transmits the image signal obtained from the imaging unit 702 as the RAW data to the CCU 601 via the transmission cable 700.

Furthermore, the communication unit 704 receives a control signal for controlling driving of the camera head 502 from the CCU 601 and supplies the control signal to the camera head control unit 705. The control signal includes information regarding image pickup conditions such as, for example, information that a frame rate of a picked up image is designated, information that an exposure value upon image picking up is designated and/or information that a magnification and a focal point of a picked up image are designated.

Note that the imaging conditions such as the frame rate, exposure value, magnification, and focus described above may be appropriately specified by the user, or may be automatically set by the control unit 713 of the CCU 601 on the basis of the acquired image signal. In the latter case, the endoscope 500 is equipped with a so-called auto exposure (AE) function, an auto focus (AF) function, and an auto white balance (AWB) function.

The camera head control unit 705 controls the driving of the camera head 502 on the basis of the control signal from the CCU 601 received via the communication unit 704.

The communication unit 711 includes a communication device for transmitting and receiving various types of information to and from the camera head 502. The communication unit 711 receives the image signal transmitted from the camera head 502 via the transmission cable 700.

Furthermore, the communication unit 711 transmits the control signal for controlling the driving of the camera head 502 to the camera head 502. The image signal and the control signal can be transmitted by electrical communication, optical communication or the like.

The image processing unit 712 performs various types of image processing on the image signal which is the RAW data transmitted from the camera head 502.

The control unit 713 performs various types of control regarding imaging of the surgical site and the like by the endoscope 500 and display of the captured image obtained by the imaging of the surgical site and the like. For example, the control unit 713 generates the control signal for controlling the driving of the camera head 502.

Furthermore, the control unit 713 allows the display device 602 to display the captured image including the surgical site and the like on the basis of the image signal subjected to the image processing by the image processing unit 712. At this time, the control unit 713 may recognize various objects in the captured image using various image recognition technologies. For example, the control unit 713 may detect edge shapes, colors, and the like of the objects included in the captured image, to recognize the surgical tool such as forceps, a specific living body site, bleeding, mist when the energy treatment tool 512 is used, and the like. At the time of causing the display device 602 to display the captured image, the control unit 713 may overlay various types of surgery assistance information on the image of the surgical site using the recognition result. The surgery assistance information is displayed to be overlaid and presented to the surgeon 531, which can reduce the burden on the surgeon 531 and enable the surgeon 531 to reliably proceed with surgery.

The transmission cable 700 connecting the camera head 502 and the CCU 601 is an electric signal cable compatible with communication of electric signals, an optical fiber compatible with optical communication, or a composite cable thereof.

Here, in the illustrated example, the communication is performed wired using the transmission cable 700, but the communication between the camera head 502 and the CCU 601 may be performed wirelessly.

Although the embodiments of the present disclosure have been described above, these embodiments may be implemented with various modifications within a scope not departing from the gist of the present disclosure. For example, two or more embodiments may be implemented in combination.

Note that the present disclosure can also have the following configurations.

(1)

A solid-state imaging device including:
a first substrate;
a photoelectric conversion unit provided in the first substrate;
a floating diffusion portion provided in the first substrate; and
a capacitor including a first electrode electrically connected or connectable to the floating diffusion portion, a second electrode different from the first electrode, and a ferroelectric film or an antiferroelectric film provided between the first electrode and the second electrode.
   (2)

The solid-state imaging device according to (1), in which the ferroelectric film contains hafnium (Hf), zirconium (Zr), niobium (Nb), scandium (Sc), yttrium (Y), lanthanum (La), germanium (Ge), or silicon (Si).

(3)

The solid-state imaging device according to (1), in which the first electrode is electrically connected to the floating diffusion portion, a source or a drain of a transfer transistor, and a gate of an amplification transistor.

(4)

The solid-state imaging device according to (1), further including a wiring that applies a predetermined voltage to the second electrode.

(5)

The solid-state imaging device according to (1), in which a sum of a capacitance of the floating diffusion portion and a capacitance of the capacitor is switchable to at least two types of values.

(6)

The solid-state imaging device according to (5), in which the sum of the capacitance of the floating diffusion portion and the capacitance of the capacitor is switchable using hysteresis of the capacitor.

(7)

The solid-state imaging device according to (1), in which the first electrode is electrically connectable to the floating diffusion portion, a source or a drain of a transfer transistor, and a gate of an amplification transistor via a switch transistor.

(8)

The solid-state imaging device according to (1), in which a sum of a capacitance of the floating diffusion portion and a capacitance of the capacitor is switchable to three or more types of values.

(9)

The solid-state imaging device according to (8), in which the sum of the capacitance of the floating diffusion portion and the capacitance of the capacitor is switchable using hysteresis of the capacitor and on/off of a switch transistor between the capacitor and the floating diffusion portion.

(10)

The solid-state imaging device according to (8), in which the sum of the capacitance of the floating diffusion portion and the capacitance of the capacitor is switchable using hysteresis of the capacitor and adjustment of a voltage applied to the capacitor.

(11)

The solid-state imaging device according to (1), further including
a lens provided on a second surface side of the first substrate,
in which the capacitor is provided on a first surface side of the first substrate.
   (12)

The solid-state imaging device according to (11), further including, on the first surface side of the first substrate, a first region including a transfer transistor, a second region including a pixel transistor other than the transfer transistor, and a third region including a logic circuit.

(13)

The solid-state imaging device according to (1), further including: a second substrate bonded to the first substrate; and
a logic circuit provided on the second substrate.
   (14)

The solid-state imaging device according to (13), further including
a third substrate bonded to the first substrate and the second substrate,
in which the capacitor is provided in the third substrate or in a third insulating film provided on the third substrate.
   (15)

The solid-state imaging device according to (13), in which
the first electrode is provided in a first insulating film provided on the first substrate, and
the second electrode is provided in a second insulating film provided on the second substrate.
   (16)

The solid-state imaging device according to (1), in which the capacitor is provided in an element isolation groove.

(17)

The solid-state imaging device according to (1), in which the capacitor is shared by a plurality of pixels.

(18)

The solid-state imaging device according to (17), further including, as the capacitor, a first capacitor including the second electrode to which a predetermined voltage is applied from a first wiring, and a second capacitor including the second electrode to which a predetermined voltage is applied from a second wiring.

(19)

The solid-state imaging device according to (1), in which the capacitor is electrically connected or connectable to the floating diffusion portion by a second contact plug different from a first contact plug that electrically connects the floating diffusion portion and an amplification transistor.

(20)

The solid-state imaging device according to (1), further including:
as the capacitor, a plurality of partial capacitors electrically connected or connectable to the floating diffusion portion; and
a selection unit that selects one or more partial capacitors from the plurality of capacitors, and sets a sum of capacitances of the selected partial capacitors as a capacitance of the capacitor.

### REFERENCE SIGNS LIST

1 Pixel
2 Pixel array region
3 Control circuit
4 Vertical drive circuit
5 Column signal processing circuit
6 Horizontal drive circuit
7 Output circuit
8 Vertical signal line
9 Horizontal signal line
11 Contact plug
12 Wiring
12′ Wiring
12″ Wiring
13 Contact hole
13′ Wiring
13″ Wiring
14 Wiring
14′ Wiring
14″ Wiring
15 Wiring
15′ Wiring
15″ Wiring
21 Substrate
21a Well region
21b Diffusion region
21c Diffusion region
21d Diffusion region
21e Diffusion region
22 Element isolation insulating film
23 Gate insulating film
24 Gate electrode
25 Sidewall insulating film
26 Interlayer insulating film
27 Electrode
28 Ferroelectric film
28′ Antiferroelectric film
29 Electrode
31 Via plug
31′ Via plug
32 Wiring
32′ Wiring
33 Via plug
33′ Via plug
34 Wiring
34′ Wiring
35 Via plug
35′ Via plug
36 Wiring
36′ Wiring
41 On-chip filter
42 On-chip lens
51 Substrate
51a Diffusion region
51b Diffusion region
52 Gate insulating film
53 Gate electrode
54 Sidewall insulating film
55 Interlayer insulating film
56 Contact plug
56′ Wiring
57 Contact hole
57′ Multilayer wiring structure
58 Via plug
58′ Via plug
59 Wiring
59′ Wiring
61 Substrate
62 Gate insulating film
63 Gate electrode
64 Sidewall insulating film
65 Interlayer insulating film
66 Via plug
67 Wiring
68 Via plug
69 Wiring
71 Substrate
72 Wiring
73 Wiring
74 Wiring
74′ Wiring
81 Contact plug
91 Connection portion
91a Pad portion
91b Pad portion
91c Via portion
91d Via portion
92 Signal processing unit
92a A/D converter
92b Reference voltage generation unit
92c Data latch unit
92d Current source
92e Decoder
92f Row decoder
92g I/F unit
93 Memory unit
94 Data processing unit
95 Control unit
96 Row selection unit

1. A solid-state imaging device comprising:
a first substrate;
a photoelectric conversion unit provided in the first substrate;
a floating diffusion portion provided in the first substrate; and
a capacitor including a first electrode electrically connected or connectable to the floating diffusion portion, a second electrode different from the first electrode, and a ferroelectric film or an antiferroelectric film provided between the first electrode and the second electrode.

2. The solid-state imaging device according to claim 1, wherein the ferroelectric film contains hafnium (Hf), zirconium (Zr), niobium (Nb), scandium (Sc), yttrium (Y), lanthanum (La), germanium (Ge), or silicon (Si).

3. The solid-state imaging device according to claim 1, wherein the first electrode is electrically connected to the floating diffusion portion, a source or a drain of a transfer transistor, and a gate of an amplification transistor.

4. The solid-state imaging device according to claim 1, further comprising a wiring that applies a predetermined voltage to the second electrode.

5. The solid-state imaging device according to claim 1, wherein a sum of a capacitance of the floating diffusion portion and a capacitance of the capacitor is switchable to at least two types of values.

6. The solid-state imaging device according to claim 5, wherein the sum of the capacitance of the floating diffusion portion and the capacitance of the capacitor is switchable using hysteresis of the capacitor.

7. The solid-state imaging device according to claim 1, wherein the first electrode is electrically connectable to the floating diffusion portion, a source or a drain of a transfer transistor, and a gate of an amplification transistor via a switch transistor.

8. The solid-state imaging device according to claim 1, wherein a sum of a capacitance of the floating diffusion portion and a capacitance of the capacitor is switchable to three or more types of values.

9. The solid-state imaging device according to claim 8, wherein the sum of the capacitance of the floating diffusion portion and the capacitance of the capacitor is switchable using hysteresis of the capacitor and on/off of a switch transistor between the capacitor and the floating diffusion portion.

10. The solid-state imaging device according to claim 8, wherein the sum of the capacitance of the floating diffusion portion and the capacitance of the capacitor is switchable using hysteresis of the capacitor and adjustment of a voltage applied to the capacitor.

11. The solid-state imaging device according to claim 1, further comprising
a lens provided on a second surface side of the first substrate,
in which the capacitor is provided on a first surface side of the first substrate.

12. The solid-state imaging device according to claim 11, further comprising, on the first surface side of the first substrate, a first region including a transfer transistor, a second region including a pixel transistor other than the transfer transistor, and a third region including a logic circuit.

13. The solid-state imaging device according to claim 1, further comprising: a second substrate bonded to the first substrate; and a logic circuit provided on the second substrate.

14. The solid-state imaging device according to claim 13, further comprising
a third substrate bonded to the first substrate and the second substrate,
wherein the capacitor is provided in the third substrate or in a third insulating film provided on the third substrate.

15. The solid-state imaging device according to claim 13, wherein
the first electrode is provided in a first insulating film provided on the first substrate, and
the second electrode is provided in a second insulating film provided on the second substrate.

16. The solid-state imaging device according to claim 1, wherein the capacitor is provided in an element isolation groove.

17. The solid-state imaging device according to claim 1, wherein the capacitor is shared by a plurality of pixels.

18. The solid-state imaging device according to claim 17, further comprising, as the capacitor, a first capacitor including the second electrode to which a predetermined voltage is applied from a first wiring, and a second capacitor including the second electrode to which a predetermined voltage is applied from a second wiring.

19. The solid-state imaging device according to claim 1, wherein the capacitor is electrically connected or connectable to the floating diffusion portion by a second contact plug different from a first contact plug that electrically connects the floating diffusion portion and an amplification transistor.

20. The solid-state imaging device according to claim 1, further comprising:
as the capacitor, a plurality of partial capacitors electrically connected or connectable to the floating diffusion portion; and
a selection unit that selects one or more partial capacitors from the plurality of capacitors, and sets a sum of capacitances of the selected partial capacitors as a capacitance of the capacitor.
